(19) United States
(12) Patent Application Publication
(10) Pub. No.: US 2025/0294752 A1
(43) Pub. Date: Sep. 18, 2025

(54) SEMICONDUCTOR STORAGE DEVICE AND METHOD OF MANUFACTURING SEMICONDUCTOR STORAGE DEVICE

(71) Applicant: Kioxia Corporation, Tokyo (JP)

(72) Inventors: Takeshi SAKAGUCHI, Yokkaichi Mie (JP); Yosuke MITSUNO, Yokkaichi Mie (JP)

(73) Assignee: Kioxia Corporation, Tokyo (JP)

(21) Appl. No.: 18/976,955

(22) Filed: Dec. 11, 2024

(30) Foreign Application Priority Data
Mar. 18, 2024 (JP) 2024-042384

(51) Int. Cl. H10B 43/27; H01L 23/00; H01L 25/065; H01L 25/18; H10B 41/10; H10B 41/27; H10B 43/10; H10B 80/00

(52) U.S. Cl. CPC H10B 43/27; H01L 24/08; H01L 25/0657; H01L 25/18; H10B 41/10; H10B 41/27; H10B 43/10; H10B 80/00; H01L 2224/08145; H01L 2924/1431; H01L 2924/14511

(57) ABSTRACT

A semiconductor storage device according to one embodiment includes the first chip and a second chip. The second chip is adhered to the first chip. The second chip includes a multi-layered body, a columnar body, a semiconductor layer, a first wiring, and a second wiring. The columnar body has a first end portion. The semiconductor layer has a first semiconductor portion, a second semiconductor portion, and a third semiconductor portion. The first semiconductor portion includes a first part along the first end of the multi-layered body and a second part covering the first end portion of the columnar body. The first semiconductor portion and the second semiconductor portion contain impurities forming a p-type semiconductor. The third semiconductor portion contains impurities forming an n-type semiconductor. The first gate electrode layer includes a part overlapping the first semiconductor portion when viewed in a first direction.

### CROSS-REFERENCE TO RELATED APPLICATION

This application is based upon and claims the benefit of priority from Japanese Patent Application No. 2024-042384, filed on Mar. 18, 2024, the entire contents of which are incorporated herein by reference.

### FIELD

An embodiment of the present invention relates to a semiconductor storage device and a method of manufacturing a semiconductor storage device.

### BACKGROUND ART

NAND-type flash memories including three-dimensionally disposed memory cells are known.

### BRIEF DESCRIPTION OF THE DRAWINGS

FIG. 1 is a block diagram showing a part of a semiconductor storage device of a first embodiment.

FIG. 2 is a view showing an equivalent circuit of a part of a memory cell array of the first embodiment.

FIG. 3 is a cross-sectional view showing a part of the semiconductor storage device of the first embodiment.

FIG. 4 is an enlarged cross-sectional view showing a region surrounded by line F4 in the semiconductor storage device shown in FIG. 3.

FIG. 5 is a cross-sectional view showing the semiconductor storage device shown in FIG. 4 along line F5-F5.

FIG. 6 is a cross-sectional view showing the semiconductor storage device shown in FIG. 3 along line F6-F6.

FIG. 7 is an explanatory cross-sectional view showing a semiconductor layer of the first embodiment.

FIG. 8 is a cross-sectional view taken along line F8-F8 in the constitution shown in FIG. 7.

FIG. 9 is an explanatory cross-sectional view showing a method of manufacturing a semiconductor storage device of the first embodiment.

FIG. 10 is another explanatory cross-sectional view showing the method of manufacturing a semiconductor storage device of the first embodiment.

FIG. 11 is another explanatory cross-sectional view showing the method of manufacturing a semiconductor storage device of the first embodiment.

FIG. 12 is an explanatory view showing reading operation of the semiconductor storage device of the first embodiment.

FIG. 13 is an explanatory cross-sectional view showing reading operation of the semiconductor storage device of the first embodiment.

FIG. 14 is an explanatory view showing writing operation of the semiconductor storage device of the first embodiment.

FIG. 15 is an explanatory view showing erasing operation of the semiconductor storage device of the first embodiment.

FIG. 16 is an explanatory cross-sectional view showing erasing operation of the semiconductor storage device of the first embodiment.

FIG. 17 is a cross-sectional view showing a part of a semiconductor storage device of a second embodiment.

FIG. 18 is a cross-sectional view showing a part of a semiconductor storage device of a third embodiment.

FIG. 19 is a cross-sectional view taken along line F19-F19 in the constitution shown in FIG. 18.

FIG. 20 is a plan view showing a part of a semiconductor storage device of a fourth embodiment.

FIG. 21 is a plan view showing a part of a semiconductor storage device of a fifth embodiment.

### DETAILED DESCRIPTION

A semiconductor storage device according to one embodiment includes a first chip and a second chip. The second chip is adhered to the first chip. The second chip has a multi-layered body, a columnar body, a semiconductor layer, a first wiring, and a second wiring. The multi-layered body includes a plurality of gate electrode layers and a plurality of insulating layers. The plurality of gate electrode layers and the plurality of insulating layers are alternately stacked one by one in a first direction. The multi-layered body has a first end. The first end is an end on a first side in the first direction. The first side in the first direction is a side opposite to the first chip. The columnar body extends in the first direction inside the multi-layered body. The columnar body has a first end portion reaching at least the first end of the multi-layered body. The semiconductor layer has a first semiconductor portion, a second semiconductor portion, and a third semiconductor portion. The first semiconductor portion includes a first part and a second part. The first part is along the first end of the multi-layered body. The second part covers the first end portion of the columnar body. The second semiconductor portion is connected to the first semiconductor portion. The third semiconductor portion is connected to the first semiconductor portion. The first wiring is electrically connected to the second semiconductor portion. The second wiring is electrically connected to the third semiconductor portion. The first semiconductor portion and the second semiconductor portion contain impurities forming a p-type semiconductor. The third semiconductor portion contains impurities forming an n-type semiconductor. The plurality of gate electrode layers include a first gate electrode layer closest to the first end of the multi-layered body. The first gate electrode layer includes a part overlapping the first semiconductor portion when viewed in the first direction.

Hereinafter, a semiconductor storage device and a method of manufacturing a semiconductor storage device of an embodiment will be described with reference to the drawings. In the following description, the same signs will be applied to constituents having the same or similar functions. Furthermore, duplicate description of the constituents may be omitted. In the following description, when the reference signs with numerals and alphabetical characters at the end for distinguishment do not need to be distinguished from each other, the numerals and the alphabetical characters at the end may be omitted.

In this application, terms are defined as follows. “Parallel”, “orthogonal”, and “the same” may include cases of “substantially parallel”, “substantially orthogonal”, and “substantially the same”, respectively. “Connection” is not limited to mechanical connection and may include electrical connection. That is, “connection” is not limited to a case in which a plurality of elements are directly connected and may include a case in which a plurality of elements are connected with another element interposed therebetween. The term “overlapping” is not limited to a case in which a plurality of elements are in contact with each other and may include a case in which a plurality of elements are separated (a case in which projected images of a plurality of elements are superimposed when viewed in a certain direction).

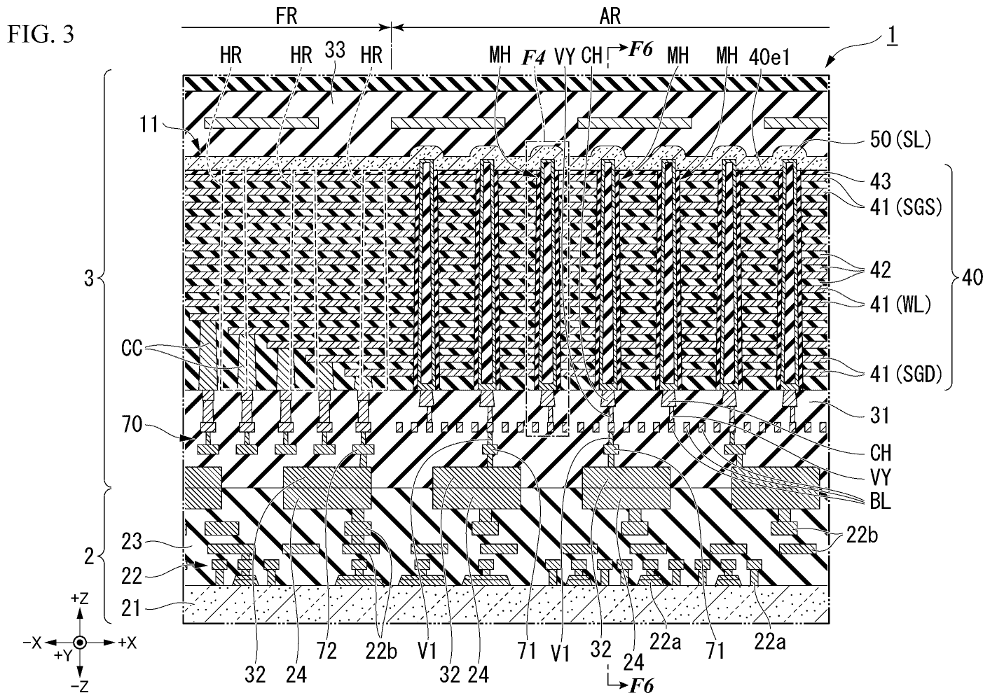

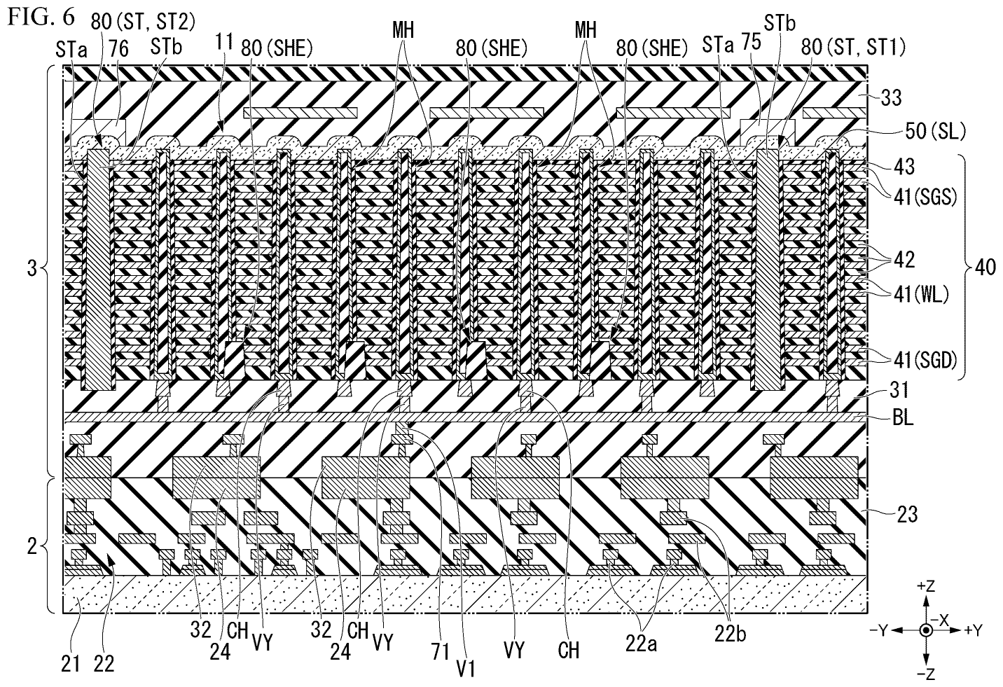

A +X direction, a −X direction, a +Y direction, a −Y direction, a +Z direction, and a −Z direction are defined as follows. The +X direction is a direction in which word lines WL (which will be described below) extend (refer to FIG. 3). The −X direction is a direction opposite to the +X direction. When there is no need to distinguish between the +X direction and the −X direction, it will be simply referred to as the X direction. The +Y direction is a direction intersecting (for example, orthogonal to) the X direction. The +Y direction is a direction in which bit lines BL extend (refer to FIG. 6). The −Y direction is a direction opposite to the +Y direction. When there is no need to distinguish between the +Y direction and the −Y direction, it will be simply referred to as the Y direction. The +Z direction is a direction intersecting (for example, orthogonal to) the X direction and the Y direction. The +Z direction is a direction toward a multi-layered body 40 from the bit lines BL (which will be described below) (refer to FIG. 3). The −Z direction is a direction opposite to the +Z direction. When there is no need to distinguish between the +Z direction and the −Z direction, it will be simply referred to as the Z direction. In this application, a side in the +Z direction may be referred to as “upward”, and a side in the −Z direction may be referred to as “downward”. However, these expressions are used for the sake of convenience of description and do not stipulate the direction of gravity. The Z direction is an example of “a first direction”. The X direction is an example of “a second direction”. In addition, in the drawings described below, illustration of constitutions not related to the description may be omitted.

### First Embodiment

### 1. Constitution of Semiconductor Storage Device

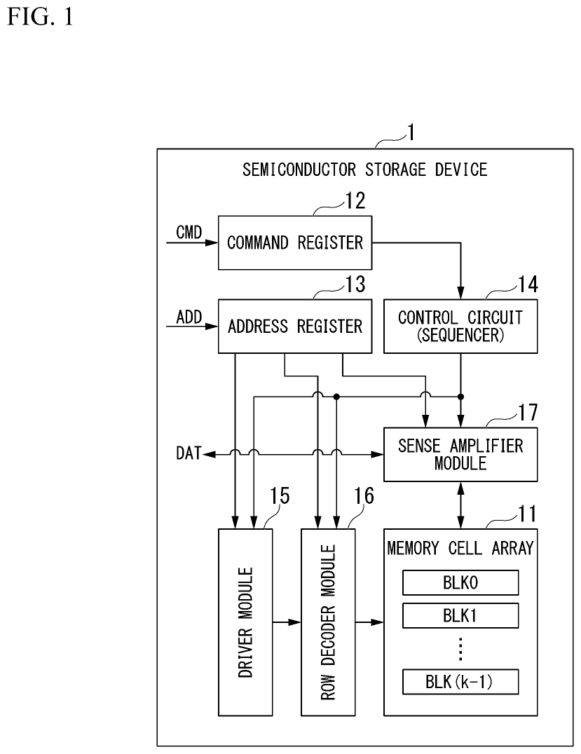

FIG. 1 is a block diagram showing a part of a semiconductor storage device 1. For example, the semiconductor storage device 1 is a non-volatile semiconductor storage device. The semiconductor storage device 1 is a NAND-type flash memory. The semiconductor storage device 1 can be connected to an external host device. The semiconductor storage device 1 is used as a storage space for the host device. For example, the semiconductor storage device 1 includes a memory cell array 11, a command register 12, an address register 13, a control circuit (sequencer) 14, a driver module 15, a row decoder module 16, and a sense amplifier module 17.

The memory cell array 11 includes a plurality of blocks BLK0 to BLK(k−1) (k is an integer equal to or larger than 1). The blocks BLK are a set of memory cell transistors. The blocks BLK are used as units of data erasure. A plurality of bit lines and a plurality of word lines are provided in the memory cell array 11. Each of the memory cell transistors is associated with one bit line and one word line.

The command register 12 holds commands CMD received by the semiconductor storage device 1 from the host device. The address register 13 holds address information ADD received by the semiconductor storage device 1 from the host device. The address information ADD is used when selecting the block BLK, the word line, and the bit line. The control circuit 14 controls various operations of the semiconductor storage device 1. For example, the control circuit 14 executes writing operation, reading operation, erasing operation, or the like of data on the basis of the commands CMD held in the command register 12.

The driver module 15 includes a voltage generation circuit and generates voltages used in various operations of the semiconductor storage device 1. The row decoder module 16 transfers a voltage, which has been applied to a signal line corresponding to the selected word line, to the selected word line. In writing operation, the sense amplifier module 17 applies a desired voltage to each of the bit lines. In reading operation, the sense amplifier module 17 determines data stored in each of the memory cell transistors on the basis of the voltage of each of the bit lines. In this operation, the sense amplifier module 17 transfers determination results to the host device as reading data DAT.

### 2. Electrical Constitution of Memory Cell Array

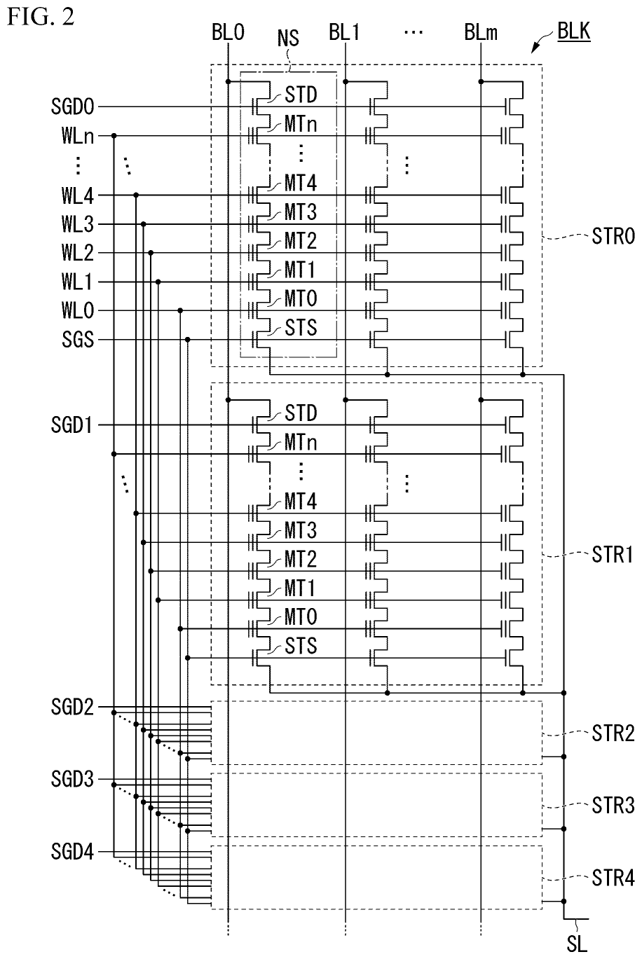

FIG. 2 is a view showing an equivalent circuit of a part of the memory cell array 11. FIG. 2 shows one block BLK included in the memory cell array 11. The block BLK includes a plurality of strings STR (for example, five strings STR0 to STR4).

Each of the strings STR includes a plurality of NAND strings NS which are respectively associated with bit lines BL0 to BLm (m is an integer equal to or larger than 1). Each of the NAND strings NS includes a plurality of memory cell transistors MT0 to MTn (n is an integer equal to or larger than 1), one or more drain-side selection transistors STD, and one or more source-side selection transistors STS.

In each of the NAND strings NS, the memory cell transistors MT0 to MTn are connected in series. Each of the memory cell transistors MT includes a control gate and a charge accumulation portion. The control gate of the memory cell transistor MT is connected to any of the word lines WL0 to WLn. In each of the memory cell transistors MT, charge is accumulated in the charge accumulation portion in response to the voltage applied to the control gate via the word line WL, and data is held in a non-volatile manner.

A drain of the drain-side selection transistor STD is connected to the bit line BL corresponding to the NAND string NS. A source of the drain-side selection transistor STD is connected to one end of each of the memory cell transistors MT0 to MTn connected in series. The control gate of the drain-side selection transistor STD is connected to any of drain-side selection gate lines SGD0 to SGD4. The drain-side selection transistor STD is electrically connected to the row decoder module 16 via the drain-side selection gate line SGD. When a predetermined voltage is applied to the corresponding drain-side selection gate line SGD, the drain-side selection transistor STD connects the NAND string NS and the bit line BL.

A drain of the source-side selection transistor STS is connected to the other end of each of the memory cell transistors MT0 to MTn connected in series. A source of the source-side selection transistor STS is connected to a source line SL. The control gate of the source-side selection transistor STS is connected to a source-side selection gate line SGS. When a predetermined voltage is applied to the source-side selection gate line SGS, the source-side selection transistor STS connects the NAND string NS and the source line SL.

In the same block BLK, the control gates of the memory cell transistors MT0 to MTn are respectively connected to the corresponding word lines WL0 to WLn in common. In the same string STR, the control gates of the drain-side selection transistors STD are respectively connected to the corresponding drain-side selection gate lines SGD in common. The control gates of the source-side selection transistors STS are respectively connected to the source-side selection gate lines SGS in common. In the memory cell array 11, the bit lines BL are shared by the NAND strings NS to which the same column address is assigned in the plurality of strings STR.

### 3. Structure of Semiconductor Storage Device

Next, a structure of the semiconductor storage device 1 will be described.

FIG. 3 is a cross-sectional view showing a part of the semiconductor storage device 1. For example, the semiconductor storage device 1 has a first chip 2 and a second chip 3. The second chip 3 is a chip adhered to the first chip 2.

### <3.1 First Chip>

The first chip 2 is a circuit chip including a peripheral circuit. For example, the first chip 2 includes a semiconductor substrate 21, a peripheral circuit 22, an insulating portion 23, and a plurality of pads 24.

For example, the semiconductor substrate 21 is a substrate serving as a base of the first chip 2. At least a part of the semiconductor substrate 21 has a plate shape lying in the X direction and the Y direction. For example, the semiconductor substrate 21 is formed of a semiconductor material such as silicon.

The peripheral circuit 22 is a circuit that causes the memory cell array 11 described above to function. The peripheral circuit 22 includes a plurality of transistors 22a and a plurality of wirings 22b. The peripheral circuit 22 includes one or more of the command register 12, the address register 13, the control circuit 14, the driver module 15, the row decoder module 16, and the sense amplifier module 17 described above. The insulating portion 23 covers the peripheral circuit 22. The plurality of pads 24 are provided on a surface of the insulating portion 23. Each of the pads 24 is electrically connected to the peripheral circuit 22.

### <3.2 Second Chip>

The second chip 3 is an array chip including the memory cell array 11. For example, the second chip 3 has the memory cell array 11, an insulating portion 31, a plurality of pads 32, and an insulating portion 33. Here, the insulating portion 31, the plurality of pads 32, and the insulating portion 33 will be described, and the memory cell array 11 will be described below.

The insulating portion 31 covers the memory cell array 11 from the side in the −Z direction. The plurality of pads 32 are provided on a surface of the insulating portion 31. Each of the pads 32 is electrically connected to a wiring (for example, a wiring 71 or a wiring 72) included in a wiring portion 70 of the memory cell array 11, which will be described below. In the present embodiment, the first chip 2 and the second chip 3 are integrated by adhering the plurality of pads 24 of the first chip 2 and the plurality of pads 32 of the second chip 3 facing each other. The insulating portion 33 covers the memory cell array 11 from the side in the +Z direction.

### 4. Memory Cell Array

Next, the memory cell array 11 will be described.

As shown in FIG. 3, the memory cell array 11 includes an array region AR and a hookup region FR. A plurality of memory pillars MH (which will be described below) are provided in the array region AR. The array region AR is a region capable of storing data. A plurality of contacts CC (which will be described below) are provided in the hookup region FR. The hookup region FR is a region where a plurality of conductive layers 41 (which will be described below) and the wiring portion 70 are connected. For example, the hookup region FR is provided at each of both ends of the array region AR in the X direction. The memory pillars MH are not provided in the hookup region FR. In the hookup region FR, for example, end portions of plurality of conductive layers 41 are disposed in a stepped shape. In place of this, the hookup region FR may have penetration contacts as the contacts CC penetrating the conductive layers 41. In addition, in the hookup region FR, supports HR for supporting a plurality of insulating layers 42 (which will be described below) are disposed during a replacement step.

As shown in FIG. 3, for example, the memory cell array 11 has the multi-layered body 40, a semiconductor layer 50, the plurality of memory pillars MH, the plurality of bit lines BL, a plurality of contacts CH for memory pillars, a plurality of contacts VY for memory pillars, the contacts CC for conductive layers, the wiring portion 70, the supports HR, and a plurality of division portions 80 (refer to FIG. 6).

### <4.1 Multi-Layered Body>

First, the multi-layered body 40 will be described.

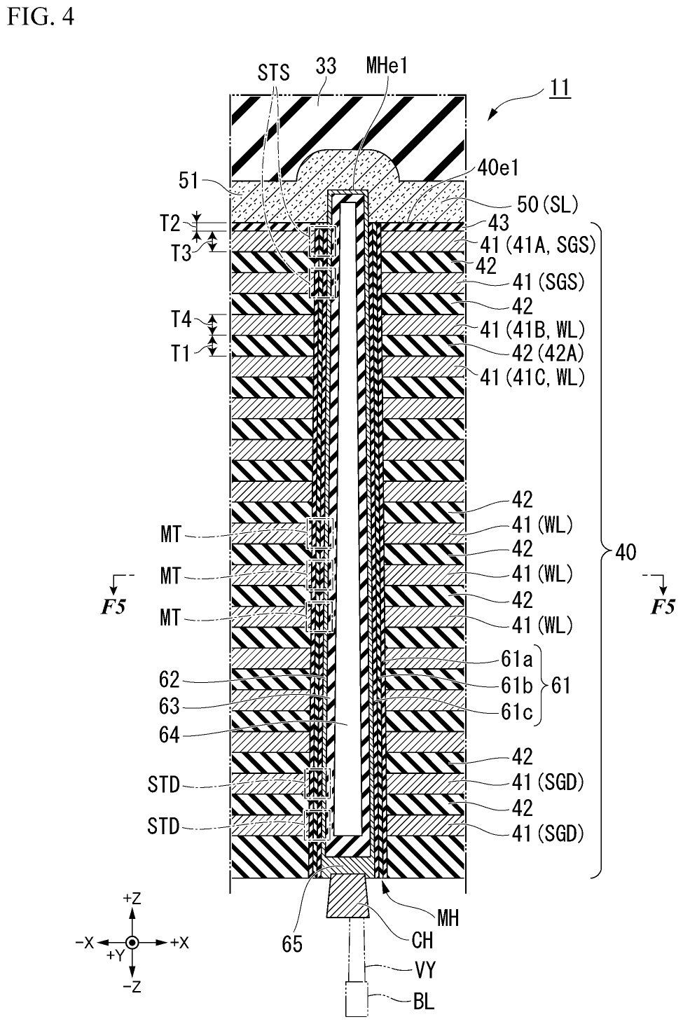

FIG. 4 is an enlarged cross-sectional view showing a region surrounded by line F4 in the semiconductor storage device 1 shown in FIG. 3. The multi-layered body 40 has a first end 40e1. The first end 40e1 is an end on the side in the +Z direction that is a side opposite to the first chip 2. For example, the first end 40e1 is an end on the side in the +Z direction that is a side opposite to the semiconductor substrate 21. In addition, for example, the multi-layered body 40 includes the plurality of conductive layers 41, the plurality of insulating layers 42, and an insulating layer 43. The plurality of conductive layers 41 and the plurality of insulating layers 42 are alternately stacked one by one in the Z direction.

The conductive layers 41 lie in the X direction and the Y direction. For example, each of the conductive layers 41 is formed of a conductive material such as tungsten or molybdenum. The conductive layer 41 is an example of “a gate electrode layer”.

One or more (for example, a plurality of) conductive layers 41 positioned below in the plurality of conductive layers 41 function as the drain-side selection gate lines SGD. The drain-side selection gate lines SGD are provided in common with respect to the plurality of memory pillars MH arranged in the X direction or the Y direction. The intersecting portions between the drain-side selection gate lines SGD and a channel layer 62 (which will be described below) of each of the memory pillars MH function as the drain-side selection transistors STD described above.

One or more (for example, a plurality of) conductive layers 41 positioned above in the plurality of conductive layers 41 function as the source-side selection gate lines SGS. The source-side selection gate lines SGS are provided in common with respect to the plurality of memory pillars MH arranged in the X direction or the Y direction. The intersecting portions between the source-side selection gate lines SGS and the channel layer 62 of each of the memory pillars MH function as the source-side selection transistors STS described above.

In the plurality of conductive layers 41, at least a part of the remaining conductive layers 41 provided between the conductive layers 41 functioning as the drain-side selection gate lines SGD and the source-side selection gate lines SGS function as the word lines WL. The word lines WL are provided in common with respect to the plurality of memory pillars MH arranged in the X direction and the Y direction. In the present embodiment, the intersecting portions between the word lines WL and the channel layer 62 of each of the memory pillars MH function as the memory cell transistors MT. The memory cell transistor MT will be described below in detail.

In the present embodiment, the plurality of conductive layers 41 include a conductive layer 41A, a conductive layer 41B, and a conductive layer 41C.

The conductive layer 41A is the conductive layer 41 positioned at the uppermost position in the plurality of conductive layers 41. The conductive layer 41A is the conductive layer 41 closest to the first end 40e1 of the multi-layered body 40 among the plurality of conductive layers 41. The conductive layer 41A is an example of “a first gate electrode layer”.

The conductive layer 41B is one conductive layer 41 included in the plurality of conductive layers 41. For example, the conductive layer 41B is a conductive layer functioning as the word line WL positioned at the top among the plurality of word lines WL. For example, the conductive layer 41B is the conductive layer 41 closest to the source-side selection gate line SGS among the plurality of word lines WL. The conductive layer 41B may be the conductive layer 41 functioning as the drain-side selection gate line SGD or may be the conductive layer 41 functioning as the source-side selection gate line SGS. The conductive layer 41B is an example of “a second gate electrode layer”.

The conductive layer 41C is the conductive layer 41 adjacent to the conductive layer 41B in the Z direction. For example, the conductive layer 41C is the conductive layer 41 positioned immediately below the conductive layer 41B. For example, the conductive layer 41C is a conductive layer functioning as the word line WL. The conductive layer 41C may be the conductive layer 41 functioning as the drain-side selection gate line SGD or may be the conductive layer 41 functioning as the source-side selection gate line SGS. The conductive layer 41C is an example of “a third gate electrode layer”.

The insulating layers 42 are provided between two conductive layers 41 adjacent to each other in the Z direction. The insulating layers 42 are interlayer insulating films insulating the two conductive layers 41. The insulating layers 42 lie in the X direction and the Y direction. For example, the insulating layers 42 are formed of a film containing silicon and oxygen. The insulating layers 42 are insulating layers formed by supplying a raw material gas and depositing the gas while causing a chemical reaction. For example, the insulating layers 42 are insulating layers formed by chemical vapor deposition (CVD). The insulating layers 42 contain carbon or the like which are incorporated due to chemical reaction during film formation.

The plurality of insulating layers 42 include an insulating layer 42A. The insulating layer 42A is provided between the conductive layer 41B (second gate electrode layer) and the conductive layer 41C (third gate electrode layer). The insulating layer 42A is an interlayer insulating film insulating the two conductive layers 41B and 41C. The insulating layer 42A is an example of “a first insulating layer”.

The insulating layer 43 is an insulating layer provided above the conductive layer 41A (first gate electrode layer). The insulating layer 43 is an insulating layer disposed between the conductive layer 41A (first gate electrode layer) and the first end 40e1 of the multi-layered body 40. An end of the insulating layer 43 on the side in the +Z direction forms the first end 40e1 of the multi-layered body 40. The insulating layer 43 lies in the X direction and the Y direction. For example, the insulating layers 42 are formed of a film containing silicon and oxygen.

For example, the insulating layer 43 is a thermal oxide film. The insulating layer 43 is a layer formed by heating a silicon layer in an oxygen atmosphere and oxidizing a part or all of the silicon layer. The insulating layer 43 has a lower content of materials other than silicon and oxygen (for example, carbon) than the insulating layers 42. The insulating layer 43 and the insulating layers 42 have different compositions (for example, film properties). The insulating layer 43 is a film having a higher pressure resistance than the insulating layers 42. The insulating layer 43 is an example of “a second insulating layer”.

In the present embodiment, a thickness T2 of the insulating layer 43 in the Z direction (for example, minimum thickness) is smaller than a thickness T1 of the insulating layer 42 in the Z direction (for example, minimum thickness). For example, the thickness T2 of the insulating layer 43 in the Z direction (for example, minimum thickness) is equal to or smaller than half the thickness T1 of the insulating layer 42 in the Z direction (for example, minimum thickness). In the present embodiment, “the thickness T2 of the insulating layer 43 in the Z direction (for example, minimum thickness)” corresponds to a distance between the conductive layer 41A and a first semiconductor portion 51 (which will be described below) in the Z direction (for example, shortest distance).

From another viewpoint, the thickness T2 of the insulating layer 43 in the Z direction (for example, minimum thickness) is smaller than a thickness T3 of the conductive layer 41A in the Z direction. For example, the thickness T2 of the insulating layer 43 in the Z direction (for example, minimum thickness) is equal to or smaller than half the thickness T3 of the conductive layer 41A in the Z direction. In addition, from another viewpoint, the thickness T2 of the insulating layer 43 in the Z direction (for example, minimum thickness) is smaller than a thickness T4 of the conductive layer 41B in the Z direction. For example, the thickness T2 of the insulating layer 43 in the Z direction (for example, minimum thickness) is equal to or smaller than half the thickness T4 of the conductive layer 41B in the Z direction.

### <4.2 Semiconductor Layer (Source Line)>

The semiconductor layer 50 is provided on the first end 40e1 of the multi-layered body 40. The semiconductor layer 50 extends in the X direction and the Y direction. The semiconductor layer 50 is formed of a material containing silicon. The semiconductor layer 50 is a layer functioning as the source line SL. The semiconductor layer 50 will be described below in detail.

### <4.3 Memory Pillar>

The plurality of memory pillars MH are arranged in the X direction and the Y direction (refer to FIG. 3). Each of the memory pillars MH extends in the Z direction inside the multi-layered body 40 and penetrates the multi-layered body 40. The memory pillar MH is an example of “a columnar body”.

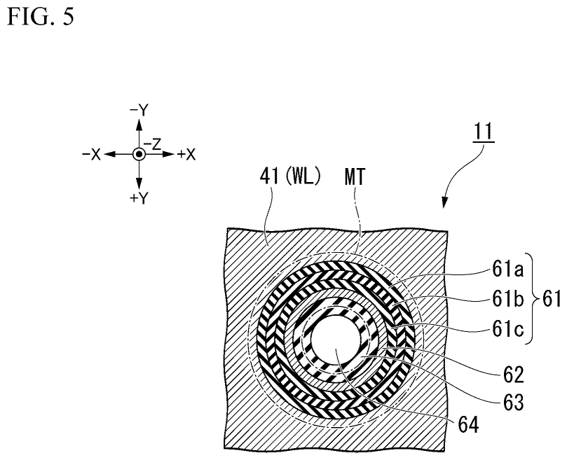

FIG. 5 is a cross-sectional view showing the semiconductor storage device 1 shown in FIG. 4 along line F5-F5. For example, the memory pillar MH has a memory film (multilayer film) 61, the channel layer 62, an insulating portion 63, a cavity portion (air gap) 64, and a cap portion 65 (refer to FIG. 4).

The memory film 61 is provided on the outer circumferential side of the channel layer 62. The memory film 61 is positioned between the plurality of conductive layers 41 and the channel layer 62. For example, the memory film 61 includes a block insulating film 61a, a charge trapping film 61b, and a tunnel insulating film 61c.

The block insulating film 61a is provided between the plurality of conductive layers 41 and the charge trapping film 61b. The block insulating film 61a is an insulating film for suppressing back-tunneling. Back-tunneling is a phenomenon in which charge returns from the word line WL to the charge trapping film 61b. The block insulating film 61a is formed to have an annular shape extending in the Z direction. For example, the block insulating film 61a is provided over the entire length of the memory pillar MH in the Z direction except for a first end portion MHe1 of the memory pillar MH (which will be described below). For example, the block insulating film 61a is a multi-layered structure film in which a plurality of insulating films such as films containing silicon and oxygen or films containing metal and oxygen are stacked. An aluminum oxide is an example of a film containing metal and oxygen. The block insulating film 61a may contain a material having a high dielectric constant (high-k material), such as silicon nitride or hafnium oxide.

The charge trapping film 61b is positioned between the block insulating film 61a and the tunnel insulating film 61c. The charge trapping film 61b is formed to have an annular shape extending in the Z direction. For example, the charge trapping film 61b is provided over the entire length of the memory pillar MH in the Z direction except for the first end portion MHe1 of the memory pillar MH. The charge trapping film 61b is a functional film having many crystal defects (trapping levels) and is capable of trapping charge in the crystal defects. For example, the charge trapping film 61b is formed of a film containing silicon and nitrogen. In the charge trapping film 61b, a part adjacent to each of the word lines WL is an example of “a charge accumulation portion” capable of storing information by accumulating charge.

The tunnel insulating film 61c is provided between the channel layer 62 and the charge trapping film 61b. For example, the tunnel insulating film 61c has an annular shape along the outer circumferential surface of the channel layer 62. The tunnel insulating film 61c extends in the Z direction along the channel layer 62. For example, the tunnel insulating film 61c is provided over the entire length of the memory pillar MH in the Z direction except for the first end portion MHe1 of the memory pillar MH. The tunnel insulating film 61c is a potential barrier between the channel layer 62 and the charge trapping film 61b. The tunnel insulating film 61c is formed of a film containing silicon and oxygen, or a film containing silicon, oxygen, and nitrogen.

The channel layer 62 is provided on the inward side of the memory film 61. The channel layer 62 is formed to have an annular shape. The channel layer 62 extends in the Z direction. For example, the channel layer 62 is provided over the entire length of the memory pillar MH in the Z direction. The channel layer 62 is formed of a semiconductor material such as polysilicon. The channel layer 62 may be doped with impurities. When voltages are applied to the word lines WL, the channel layer 62 forms a channel and electrically connects the bit line BL and the source line SL.

Accordingly, metal-Al-nitride-oxide-silicon (MANOS) type memory cell transistors MT are formed at the same height as the respective word lines WL by the end portions of the word lines WL adjacent to the memory pillars MH, the block insulating film 61a, the charge trapping film 61b, the tunnel insulating film 61c, and the channel layer 62. In place of the charge trapping film 61b, the memory film 61 may have a floating gate-type charge accumulation portion (floating gate electrode) as a charge accumulation portion. For example, the floating gate electrode is formed of polysilicon containing impurities.

The insulating portion 63 is provided on the inward side of the channel layer 62. The insulating portion 63 fills at least a part inside the channel layer 62. The insulating portion 63 is formed of a film containing silicon and oxygen. In the present embodiment, the insulating portion 63 is formed to have an annular shape along the inner circumferential surface of the channel layer 62 such that the cavity portion (air gap) 64 is formed therein. The cavity portion 64 may not be present. The insulating portion 63 extends in the Z direction. For example, the insulating portion 63 is provided over the most part of the memory pillar MH in the Z direction except for the lower end portion of the memory pillar MH (refer to FIG. 4).

Next, returning to FIG. 4, the cap portion 65 will be described. The cap portion 65 is provided below the insulating portion 63. The cap portion 65 is a semiconductor portion formed of a semiconductor material such as amorphous silicon or polysilicon. The cap portion 65 may be doped with impurities. The cap portion 65 is disposed on the inner circumferential side of the lower end portion of the memory film 61 and is formed integrally with the channel layer 62. The cap portion 65 forms the lower end portion of the memory pillar MH together with the lower end portion of the channel layer 62. The contact CH comes into contact with the cap portion 65 from the side in the −Z direction.

Next, the first end portion MHe1 of the memory pillar MH will be described. In the present embodiment, the first end portion MHe1 of the memory pillar MH protrudes from the first end 40e1 of the multi-layered body 40 to the side in the +Z direction. The first end portion MHe1 of the memory pillar MH comes into contact with the semiconductor layer 50. In the first end portion MHe1 of the memory pillar MH, the memory film 61 is not present, and the channel layer 62 is exposed to the outside of the memory pillar MH. In the first end portion MHe1, the channel layer 62 of the memory pillar MH comes into contact with the semiconductor layer 50 at a position on the side in the +Z direction from the first end 40e1 of the multi-layered body 40. The first end portion MHe1 of the memory pillar MH is an example of “a first end portion”. The first end portion MHe1 of the memory pillar MH does not necessarily have to protrude from the first end 40e1 of the multi-layered body 40 to the side in the +Z direction. The first end portion MHe1 of the memory pillar MH need only reach at least the first end 40e1 of the multi-layered body 40. For example, the first end portion MHe1 of the memory pillar MH may come into contact with the semiconductor layer 50 at the same position as the first end 40e1 of the multi-layered body 40.

### <4.4 Bit Line>

Next, returning to FIG. 3, the bit line BL will be described. The bit line BL is a wiring for selecting one memory pillar MH from the plurality of memory pillars MH. The plurality of bit lines BL are disposed on the downward side (side in the −Z direction) with respect to the multi-layered body 40. The plurality of bit lines BL are arranged in the X direction with an interval therebetween in the X direction. Each of the bit lines BL extends in the Y direction. Each of the bit lines BL extends so as to pass through below the plurality of corresponding memory pillars MH.

Each of the bit lines BL is connected to the channel layer 62 of the memory pillar MH via the contact VY and the contact CH. Accordingly, with a combination of the word line WL and the bit line BL, the memory cell transistor MT can be optionally selected from the plurality of memory cell transistors MT which are disposed three-dimensionally.

### <4.5 Contact for Conductive Layer>

As shown in FIG. 3, the contact CC is an electrical connection portion electrically connecting the conductive layer 41 and the wiring 72 (which will be described below) included in the wiring portion 70. For example, the plurality of contacts CC are disposed correspondingly to the hookup region FR of the memory cell array 11. The plurality of contacts CC extend in the Z direction and are connected to the conductive layers 41 different from each other.

### <4.6 Wiring Portion>

Next, the wiring portion 70 will be described. For example, the wiring portion 70 is disposed between the multi-layered body 40 and the semiconductor substrate 21. For example, the wiring portion 70 includes a plurality of wirings 71, a plurality of vias V1, a plurality of wirings 72, a plurality of wirings 75 (only one is shown in FIG. 6), and a plurality of wirings 76 (only one is shown in FIG. 6). The wiring 75 and the wiring 76 will be described below.

The wiring 71 is an electrical connection portion electrically connecting the bit line BL and the pad 32. For example, the plurality of wirings 71 are disposed below with respect to the plurality of bit lines BL. For example, each of the wirings 71 extends in the X direction or the Y direction. The vias V1 electrically connecting the wirings 71 and the bit lines BL are provided between the wirings 71 and the bit lines BL.

The wiring 72 is an electrical connection portion electrically connecting the contact CC for a conductive layer and the pad 32. The wiring 72 is electrically connected to the conductive layer 41 via the contact CC for a conductive layer. A voltage is applied to the wiring 72 in order to select the conductive layer 41 (the word line WL, the drain-side selection gate line SGD, or the source-side selection gate line SGS).

### <4.7 Support>

Next, the support HR will be described. The support HR is provided in the hookup region FR. The support HR penetrates the multi-layered body 40 in the Z direction in the hookup region FR. For example, the support HR is a columnar body having the same structure as the memory pillar MH. The support HR may be formed of an insulating portion. The support HR supports the plurality of insulating layers 42 (which will be described below) during the replacement step.

### 5. Division Portion

Next, the division portion 80 will be described.

FIG. 6 is a cross-sectional view showing the semiconductor storage device 1 shown in FIG. 3 along line F6-F6. In the present embodiment, the plurality of division portions 80 are provided in the multi-layered body 40. The plurality of division portions 80 are disposed in a manner of being divided in the Y direction. Each of the plurality of division portions 80 extends in the Z direction inside the multi-layered body 40 and divides one or more conductive layers 41 including the lowermost layer of the plurality of conductive layers 41 in the Y direction. For example, the plurality of division portions 80 include a plurality of division portions ST and a plurality of division portions SHE.

### <5.1 Division Portion ST>

The division portions ST are wall portions dividing the multi-layered body 40 in the Y direction. The plurality of division portions ST are disposed in a manner of being divided in the Y direction. The division portions ST extend in the Z direction, penetrate the multi-layered body 40. The division portions ST extend in the X direction. That is, the division portions ST are wall portions lying in the Z direction and the X direction. The division portions ST divide each of all the conductive layers 41 included in the multi-layered body 40 in the Y direction. For example, the division portions ST each include an insulating portion STa and a conductive portion STb.

The insulating portion STa extends in the Z direction and penetrates the multi-layered body 40. The insulating portion STa divides each of the plurality of conductive layers 41 included in the multi-layered body 40 in the Y direction. For example, the insulating portion STa is formed of a film containing silicon and oxygen.

The conductive portion STb is provided inside the insulating portion STa. The conductive portion STb extends in the Z direction and penetrates the multi-layered body 40. The upper end of the conductive portion STb comes into contact with the semiconductor layer 50 (source line SL). The conductive portion STb is formed of a conductive material such as tungsten or molybdenum. For example, the conductive portion STb may also function as an electrical connection portion connecting the semiconductor layer 50 (source line SL) and the wirings inside the memory cell array 11.

The division portions ST may be formed of only one of the insulating portion STa and the conductive portion STb. For example, the division portions ST may be formed using only an insulation body or may be formed using only a conductive body.

### <5.2 Division Portion SHE>

The division portions SHE are division portions shallower in the Z direction than the division portions ST and are wall portions dividing a lower end portion of the multi-layered body 40 in the Y direction. The plurality of division portions SHE are disposed in a manner of being divided in the Y direction. In the present embodiment, a plurality of (for example, four) division portions SHE are present between two division portions ST adjacent to each other in the Y direction. The division portions SHE are provided in the lower end portion of the multi-layered body 40. The division portions SHE extend in the Z direction halfway through the multi-layered body 40. The division portions SHE extend in the X direction. That is, the division portions SHE are wall portions lying in the Z direction and the X direction.

The division portions SHE penetrate a part of the conductive layers 41 including the lowermost layer of the plurality of conductive layers 41 and divide the part of the conductive layers 41 in the Y direction. For example, the division portions SHE penetrate each of all the conductive layers 41 functioning as the drain-side selection gate lines SGD. On the other hand, the division portions SHE do not reach the conductive layers 41 functioning as the word lines WL. The division portions SHE divide only the conductive layers 41 functioning as the drain-side selection gate lines SGD in the Y direction. For example, the division portion SHE are formed of a film containing silicon and oxygen.

### 6. Structure Related to Semiconductor Layer (Source Line)

Next, a structure related to the semiconductor layer 50 will be described.

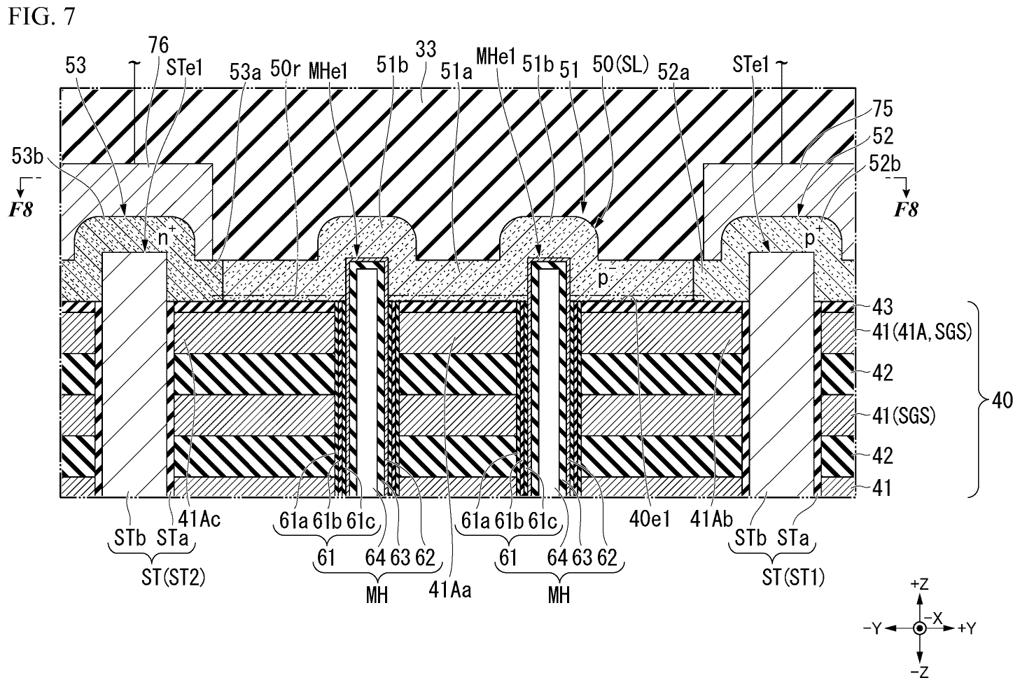

FIG. 7 is an explanatory cross-sectional view showing the semiconductor layer 50. In FIG. 7, for the sake of convenience of description, only two memory pillars MH are shown between two division portions ST (ST1, ST2) adjacent to each other in the Y direction. Actually, as shown in FIG. 6, among the plurality of division portions ST, many memory pillars MH are present between two division portions ST (ST1, ST2) adjacent to each other in the Y direction. The division portion ST1 is an example of “a first division portion”. The division portion ST2 is an example of “a second division portion”.

As shown in FIG. 7, the semiconductor layer 50 is provided along the first end 40e1 of the multi-layered body 40. In the present embodiment, the semiconductor layer 50 is provided on the first end 40e1 of the multi-layered body 40. For example, the semiconductor layer 50 includes the first semiconductor portion 51, a second semiconductor portion 52, and a third semiconductor portion 53.

### <6.1 First Semiconductor Portion>

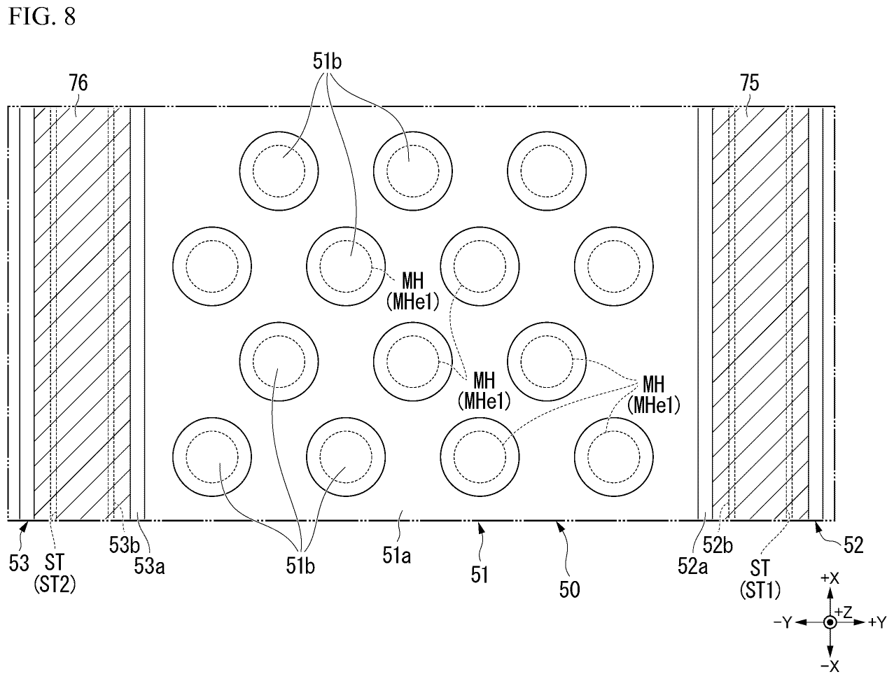

The first semiconductor portion 51 is a part connected to each of the first end portions MHe1 of the plurality of memory pillars MH. For example, the first semiconductor portion 51 extends in the Y direction in a manner of covering the first end portions MHe1 of the plurality of memory pillars MH. In addition, in the present embodiment, the first semiconductor portion 51 linearly extends in the X direction (refer to FIG. 8). For example, the first semiconductor portion 51 includes a first part 51a and a plurality of second parts 51b.

The first part 51a is provided along the first end 40e1 of the multi-layered body 40. For example, the first part 51a is provided on the first end 40e1 of the multi-layered body 40. For example, the first part 51a has a layer shape lying in the X direction and the Y direction on the first end 40e1 of the multi-layered body 40. The first part 51a is disposed between the plurality of second parts 51b in the X direction and the Y direction and connects the plurality of second parts 51b to each other. In addition, the end portion of the first part 51a on the side in the +Y direction is connected to the second semiconductor portion 52 in the Y direction. The end portion of the first part 51a on the side in the −Y direction is connected to the third semiconductor portion 53 in the Y direction.

The plurality of second parts 51b are provided correspondingly to the plurality of memory pillars MH on one-to-one basis when viewed in the Z direction (refer to FIG. 8). Each of the second parts 51b covers the first end portion MHe1 of the memory pillar MH from the side in the +Z direction. In the present embodiment, the first end portion MHe1 of the plurality of memory pillar MH protrudes from the first end 40e1 of the multi-layered body 40 to the side in the +Z direction. In the present embodiment, each of the second parts 51b rises from the first part 51a to the side in the +Z direction and covers the first end portion MHe1 of the memory pillar MH from the side in the +Z direction.

The first semiconductor portion 51 contains impurities (impurities serving as acceptors) forming a p-type semiconductor and has a conductive type of p-type (for example, p⁻-type). “Acceptors” are elements having fewer valence electrons than tetravalent elements. For example, they are trivalent elements. For example, the acceptors are boron (B).

### <6.2 Second Semiconductor Portion>

The second semiconductor portion 52 is a part to which the wiring 75 of the wiring portion 70 is connected. For example, the second semiconductor portion 52 is positioned on the side in the +Y direction with respect to the first semiconductor portion 51. The second semiconductor portion 52 is connected to the first semiconductor portion 51 in the Y direction. In the present embodiment, the second semiconductor portion 52 is provided on the first end 40e1 of the multi-layered body 40. For example, the second semiconductor portion 52 includes a first part 52a and a second parts 52b.

The first part 52a is provided along the first end 40e1 of the multi-layered body 40. For example, the first part 52a is provided on the first end 40e1 of the multi-layered body 40. The thickness of the first part 52a in the Z direction is the same as the thickness of the first part 51a of the first semiconductor portion 51 in the Z direction.

The second parts 52b covers a first end portion STe1 of the first division portion ST1 from the side in the +Z direction. In the present embodiment, the first end portion STe1 of the first division portion ST1 protrudes from the first end 40e1 of the multi-layered body 40 to the side in the +Z direction. In the present embodiment, the second parts 52b rises from the first part 52a to the side in the +Z direction and covers the first end portion STe1 of the first division portion ST1 from the side in the +Z direction.

In the present embodiment, when viewed in the Z direction, the second semiconductor portion 52 overlaps at least a part of the division portion ST1. For example, the second semiconductor portion 52 linearly extends in the X direction along the division portion ST1 (refer to FIG. 8).

The second semiconductor portion 52 contains impurities (impurities serving as acceptors) forming a p-type semiconductor and has a conductive type of p-type (for example, p⁺-type). In the present embodiment, the second semiconductor portion 52 contains more impurities forming the p-type semiconductor than the first semiconductor portion 51. The impurities forming the second semiconductor portion 52 may be the same as or different from the impurities forming the first semiconductor portion 51.

### <6.3 Third Semiconductor Portion>

The third semiconductor portion 53 is a part to which the wiring 76 of the wiring portion 70 is connected. For example, the third semiconductor portion 53 is positioned on the side in the −Y direction with respect to the first semiconductor portion 51. The third semiconductor portion 53 is connected to the first semiconductor portion 51 in the Y direction. In the present embodiment, the third semiconductor portion 53 is provided on the first end 40e1 of the multi-layered body 40. For example, the third semiconductor portion 53 has a first part 53a and a second parts 53b.

The first part 53a is provided along the first end 40e1 of the multi-layered body 40. For example, the first part 53a is provided on the first end 40e1 of the multi-layered body 40. The thickness of the first part 53a in the Z direction is the same as the thickness of the first part 51a of the first semiconductor portion 51 in the Z direction.

The second parts 53b covers the first end portion STe1 of the second division portion ST2 from the side in the +Z direction. In the present embodiment, the first end portion STe1 of the second division portion ST2 protrudes from the first end 40e1 of the multi-layered body 40 to the side in the +Z direction. In the present embodiment, the second parts 53b rises from the first part 53a to the side in the +Z direction and covers the first end portion STe1 of the second division portion ST2 from the side in the +Z direction.

In the present embodiment, when viewed in the Z direction, the third semiconductor portion 53 overlaps at least a part of the division portion ST2. For example, the third semiconductor portion 53 linearly extends in the X direction along the division portion ST2 (refer to FIG. 8).

The third semiconductor portion 53 contains impurities (impurities serving as donors) forming an n-type semiconductor and has a conductive type of n-type (for example, n⁺-type). “Donors” are elements having more valence electrons than tetravalent elements. For example, they are pentavalent elements. For example, the donors are phosphorus (P).

### <6.4 Inversion Layer>

In the present embodiment, when viewed in the Z direction, the conductive layer 41A described above (the conductive layer 41 positioned at the top among the plurality of conductive layers 41) overlaps the semiconductor layer 50. For example, the conductive layer 41A includes a first part 41Aa, a second parts 41Ab, and a third part 41Ac. When viewed in the Z direction, the first part 41Aa overlaps the first semiconductor portion 51 of the semiconductor layer 50. When viewed in the Z direction, the second parts 41Ab overlaps the second semiconductor portion 52 of the semiconductor layer 50. When viewed in the Z direction, the third part 41Ac overlaps the third semiconductor portion 53 of the semiconductor layer 50. In this application, the expression “overlapping XX” is not limited to a case of overlapping the entire region of XX and may include a case of overlapping at least a part of the region of XX.

In the present embodiment, when a voltage is applied to the conductive layer 41A, an inversion layer 50r is formed in a part of the semiconductor layer 50. For example, the inversion layer 50r is formed in the end portion of the first semiconductor portion 51 on the side in the −Z direction. The inversion layer 50r extends in the X direction and the Y direction along the first end 40e1 of the multi-layered body 40. The inversion layer 50r comes into contact with the channel layer 62 of the memory pillar MH and comes into contact with the third semiconductor portion 53. If the inversion layer 50r is formed, electrons can move between the channel layer 62 of the memory pillar MH and the third semiconductor portion 53.

### <6.5 First Wiring>

Next, the wiring 75 will be described. Hereinafter, for the sake of convenience of description, the wiring 75 will be referred to as “a first wiring 75”. The first wiring 75 is a wiring electrically connected to the second semiconductor portion 52. In the present embodiment, the first wiring 75 is provided on the second semiconductor portion 52 and comes into contact with the second semiconductor portion 52 in the +Z direction. For example, the first wiring 75 comes into contact with the first part 52a and the second parts 52b of the second semiconductor portion 52.

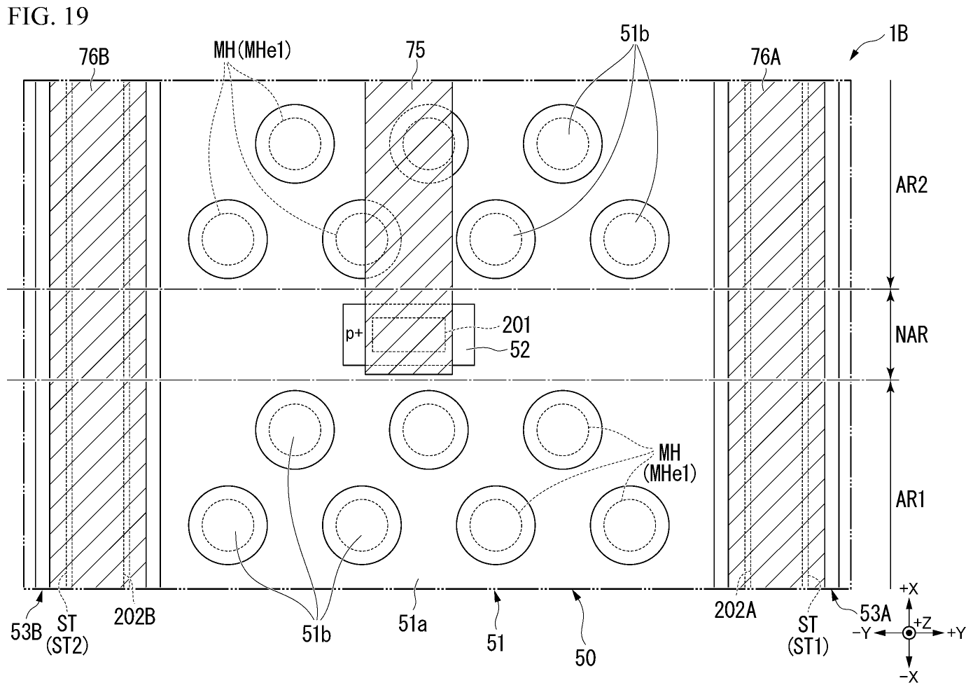

FIG. 8 is a cross-sectional view taken along line F8-F8 in the constitution shown in FIG. 7. In FIG. 8 as well, for the sake of convenience of description, only a part of the memory pillars MH is shown between two division portions ST (ST1, ST2) adjacent to each other in the Y direction. In addition, for the sake of convenience of description, FIG. 8 is a schematic view, in which illustration of the insulating portion 33 is omitted, showing the first semiconductor portion 51, the second semiconductor portion 52, the third semiconductor portion 53, the wiring 75, the wiring 76, and the like by solid lines. This definition also applies to FIGS. 19, 20, and 21 in a similar manner.

As shown in FIG. 8, the first wiring 75 linearly extends in the X direction along the second semiconductor portion 52. Disposition of the first wiring 75 is not limited to the foregoing example. For example, the first wiring 75 may be provided below the multi-layered body 40 and electrically connected to the second semiconductor portion 52 via the conductive portion STb of the division portion ST1.

### <6.6 Second Wiring>

Next, the wiring 76 will be described. Hereinafter, for the sake of convenience of description, the wiring 76 will be referred to as “a second wiring 76”. The second wiring 76 is a wiring electrically connected to the third semiconductor portion 53. In the present embodiment, the second wiring 76 is electrically insulated from the first wiring 75. In the present embodiment, the second wiring 76 is provided on the third semiconductor portion 53 and comes into contact with the third semiconductor portion 53 in the +Z direction. For example, the second wiring 76 comes into contact with the first part 53a and the second parts 53b of the third semiconductor portion 53. The second wiring 76 linearly extends in the X direction along the third semiconductor portion 53.

Disposition of the second wiring 76 is not limited to the foregoing example. For example, the second wiring 76 may be provided below the multi-layered body 40 and electrically connected to the third semiconductor portion 53 via the conductive portion STb of the division portion ST2.

### <6.7 Insulating Portion>

Returning to FIG. 7, the insulating portion 33 will be described. The insulating portion 33 is provided between the first wiring 75 and the second wiring 76 and electrically insulates the first wiring 75 and the second wiring 76. In addition, the insulating portion 33 is provided between the second semiconductor portion 52 and the third semiconductor portion 53 and electrically insulates the second semiconductor portion 52 and the third semiconductor portion 53.

### 7. Manufacturing Method

Next, a method of manufacturing the semiconductor storage device 1 will be described.

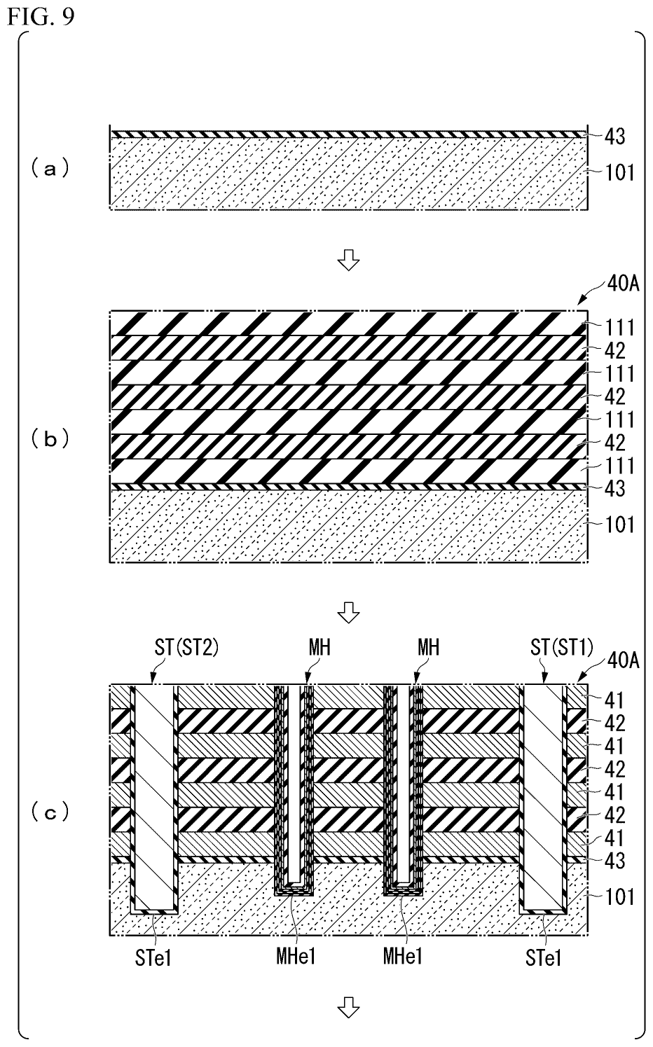

FIGS. 9 to 11 are explanatory cross-sectional views of the method of manufacturing the semiconductor storage device 1. First, a semiconductor substrate 101 is prepared. The semiconductor substrate 101 is formed of silicon. Next, the insulating layer 43 is formed on a surface of the semiconductor substrate 101 (refer to (a) in FIG. 9). In the present embodiment, the insulating layer 43 (thermal oxide film) is formed on the surface of the semiconductor substrate 101 by heating the surface of the semiconductor substrate 101 while supplying an oxidizing agent thereto.

Next, insulating layers 111 and the insulating layers 42 are alternately stacked one by one on the insulating layer 43 (refer to (b) in FIG. 9). Accordingly, a multi-layered body 40A is formed. The insulating layers 111 are sacrificial layers to be replaced by the conductive layers 41 in the following step. For example, the insulating layers 111 are formed of a material containing silicon and nitrogen.

Next, the memory pillars MH and the division portions ST are formed in the multi-layered body 40A (refer to (c) in FIG. 9). The first end portions MHe1 of the memory pillars MH and the first end portions STe1 of the division portions ST are formed inside the semiconductor substrate 101. In the present embodiment, the replacement step is performed through grooves provided when the division portions ST are formed, and the insulating layers 111 are replaced by the conductive layers 41. Accordingly, the multi-layered body 40 is formed from the multi-layered body 40A.

The second chip 3 is formed through the foregoing step. In addition, the first chip 2 is formed through another step. Furthermore, the second chip 3 is in a vertically inverted posture and is adhered to the first chip 2. For example, the pads 32 of the second chip 3 and the pads 24 of the first chip 2 are bonded so that the first chip 2 and the second chip 3 are integrated.

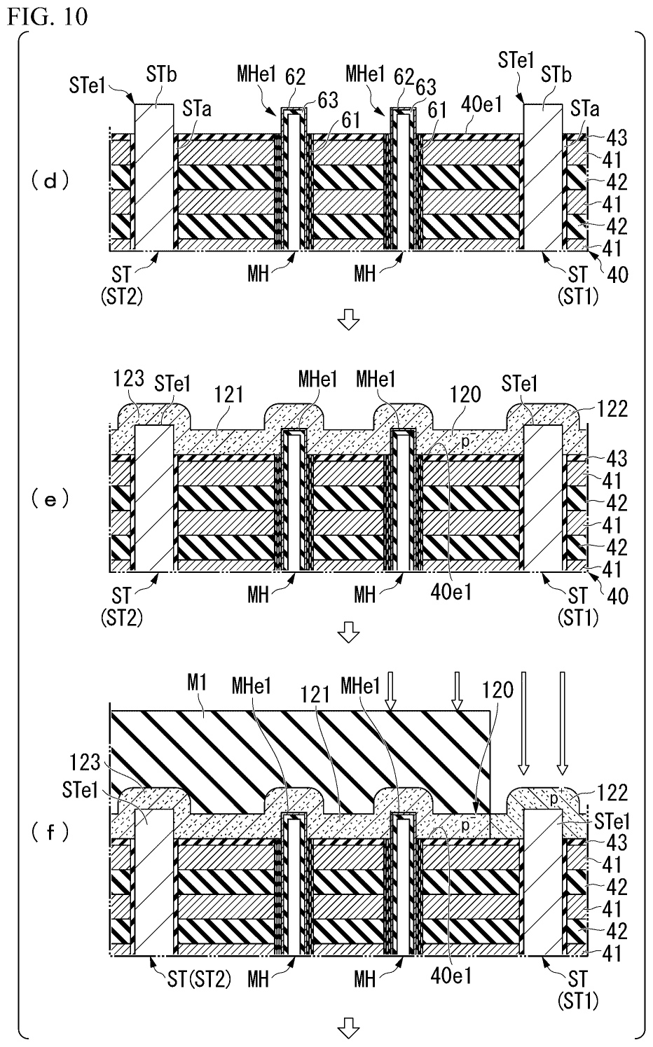

Next, at least a part of the semiconductor substrate 101 is eliminated from the second chip 3 (refer to (d) in FIG. 10). Here, for example, etching is performed. Different processing other than etching may be performed. In addition, etching and the different step may be performed. In the present embodiment, the entire semiconductor substrate 101 is eliminated except for the insulating layer 43. In addition, by etching, the memory film 61 is eliminated in the first end portion MHe1 of the memory pillar MH. Accordingly, the channel layer 62 is exposed in the first end portion MHe1 of the memory pillar MH. In addition, by etching, the insulating portion STa is eliminated in the first end portion STe1 of the division portion ST. Accordingly, the conductive portion STb is exposed in the first end portion STe1 of the division portion ST.

Next, a semiconductor layer 120 is formed on the insulating layer 43 (refer to (e) in FIG. 10). The semiconductor layer 120 contains impurities forming the p-type semiconductor. In the present embodiment, the semiconductor layer 120 is formed as a p⁻-type semiconductor. For example, the semiconductor layer 120 is formed of silicon doped with impurities. In place of this, the semiconductor layer 120 may be formed by implanting impurities after film formation.

The semiconductor layer 120 includes a first part 121, a second part 122, and a third part 123. The first part 121 is a part corresponding to the first semiconductor portion 51 of the semiconductor layer 50. The second part 122 is a part corresponding to the second semiconductor portion 52 of the semiconductor layer 50. The third part 123 is a part corresponding to the third semiconductor portion 53 of the semiconductor layer 50.

Next, for example, by lithography, a mask M1 covering the first part 121 and the third part 123 of the semiconductor layer 120 is formed (refer to (f) in FIG. 10). Next, in a state in which the mask M1 is provided, impurities forming the p-type semiconductor are additionally implanted into the second part 122 of the semiconductor layer 120. Accordingly, the second part 122 of the semiconductor layer 120 is formed as a p⁺-type semiconductor.

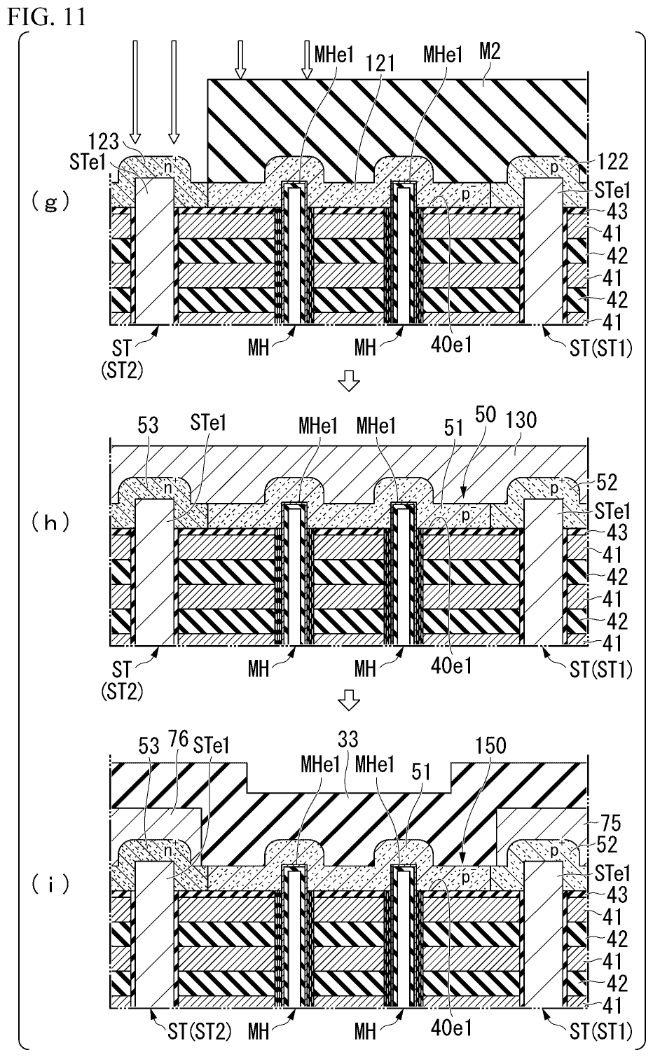

Next, for example, by lithography, a mask M2 covering the first part 121 and the second part 122 of the semiconductor layer 120 is formed (refer to (g) in FIG. 11). Next, in a state in which the mask M2 is provided, impurities forming the n-type semiconductor are additionally implanted into the third part 123 of the semiconductor layer 120. Accordingly, the third part 123 of the semiconductor layer 120 is formed as an n⁺-type semiconductor.

Next, annealing (for example, laser annealing) is performed for activation. Accordingly, the first part 121 of the semiconductor layer 120 serves as the first semiconductor portion 51. The second part 122 of the semiconductor layer 120 serves as the second semiconductor portion 52. The third part 123 of the semiconductor layer 120 serves as the third semiconductor portion 53.

Next, a conductive material (for example, metal material) is supplied to the semiconductor layer 50 thereon, and a conductive layer 130 is formed on the semiconductor layer 50 (refer to (h) in FIG. 11). Next, by patterning, unnecessary parts are eliminated from the conductive layer 130, and the first wiring 75 and the second wiring 76 are formed from the conductive layer 130 (refer to (i) in FIG. 11). Next, the insulating portion 33 is provided so as to fill a gap between the first wiring 75 and the second wiring 76. Thereafter, a wiring of an upper layer included in the wiring portion 70 is formed. Accordingly, the semiconductor storage device 1 is completed.

The method of manufacturing the semiconductor storage device 1 is not limited to the foregoing example. For example, the insulating layer 43 may be formed after the first chip 2 and the second chip 3 are adhered and the semiconductor substrate 101 is eliminated from the second chip 3. In addition, a part or the entirety of the semiconductor layer 50 may be formed before the first chip 2 and the second chip 3 are pasted. For example, a part or the entirety of the semiconductor layer 50 may be formed before the insulating layer 43 as a part of the semiconductor substrate 101. In this case, for example, the semiconductor layer 50 may be formed by the remaining portion of the semiconductor substrate 101 after the first chip 2 and the second chip 3 are adhered and unnecessary parts of the semiconductor substrate 101 are eliminated.

### 8. Operational Examples

Next, operational examples of the semiconductor storage device 1 will be described. Unless otherwise specified, the following control is executed by the control circuit (sequencer) 14.

### <8.1 Reading Operation>

First, reading operation will be described.

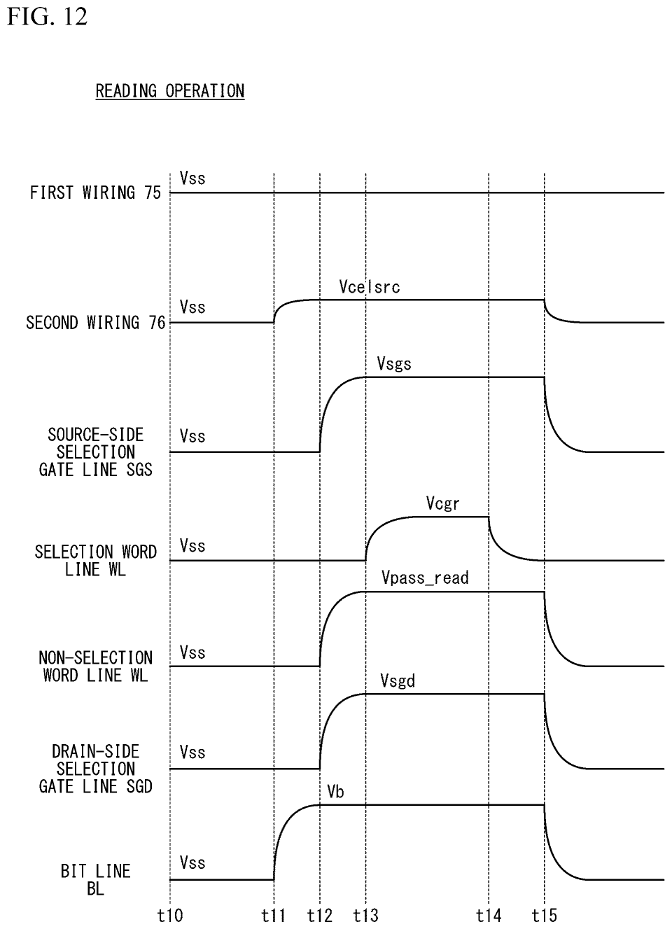

FIG. 12 is an explanatory view showing reading operation. Here, the memory cell transistor MT that is a data reading target will be referred to as “a selected memory cell transistor MT”. The word line WL corresponding to the selected memory cell transistor MT will be referred to as “a selected word line WL”. On the other hand, the memory cell transistor MT that is not a data reading target will be referred to as “an unselected memory cell transistor MT”. The word line WL corresponding to the unselected memory cell transistor MT will be referred to as “an unselected word line WL”. The bit line BL means the bit line BL corresponding to the selected memory cell transistor MT.

As shown in FIG. 12, at a time t0, the first wiring 75, the second wiring 76, the source-side selection gate line SGS, the selected word line WL, the unselected word line WL, the drain-side selection gate line SGD, and the bit line BL have a ground potential Vss (for example, 0 V) under the control of the control circuit 14.

From a time t11, the control circuit 14 maintains the voltage of the bit line BL at a voltage Vbl. The voltage Vbl is higher than the voltage Vss. In addition, from the time t11, the control circuit 14 maintains the voltage of the second wiring 76 at a voltage Vcelsrc. The voltage Vcelsrc is lower than the voltage Vbl. The voltage Vbl and the voltage Vcelsrc are continuously applied until a time t15, for example.

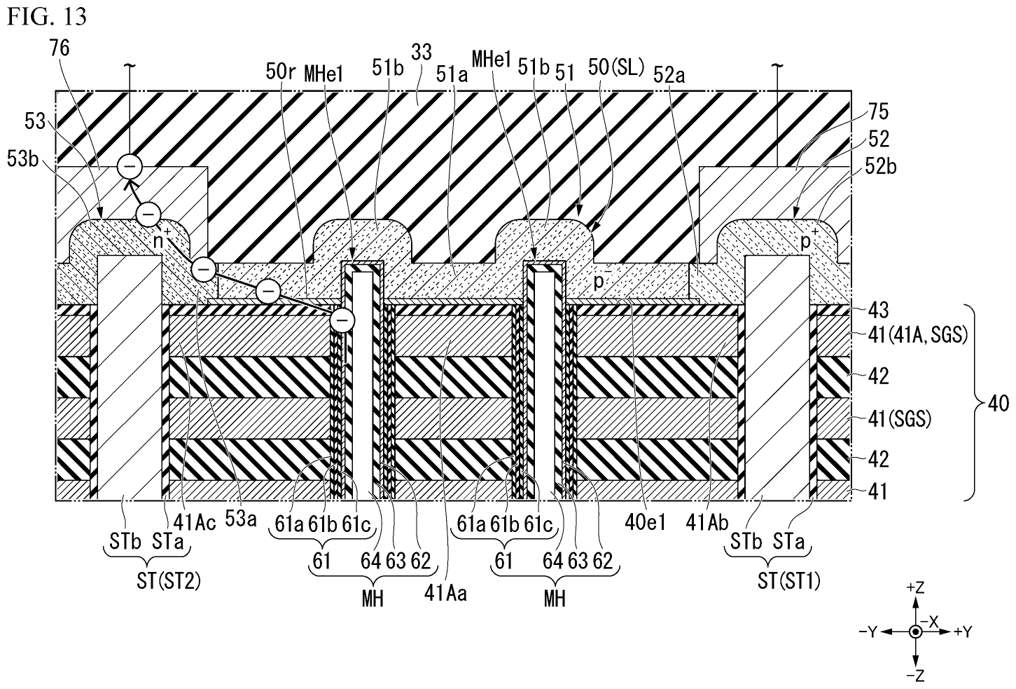

From a time t12, the control circuit 14 applies a voltage Vsgs to the source-side selection gate line SGS. The voltage Vsgs is a voltage for causing the source-side selection transistor STS to be in an ON state (conductive state). In addition, the voltage Vsgs is a voltage at which the inversion layer 50r (refer to FIG. 13) is formed in the semiconductor layer 50 when the voltage Vsgs is applied to the conductive layer 41A.

A voltage higher than the voltage applied to the different conductive layer 41 which will become the source-side selection gate line SGS may be applied to the conductive layer 41A in order to form the inversion layer 50r in the semiconductor layer 50. In the present embodiment, since the insulating layer 43 is thin, the inversion layer 50r can be formed in the semiconductor layer 50 even if the voltage applied to the conductive layer 41A is low. For this reason, the voltage Vsgs applied to the conductive layer 41A is the same as the voltage Vsgs applied to the different conductive layer 41 which will become the source-side selection gate line SGS.

In addition, from the time t12, the control circuit 14 applies a voltage Vsgd to the drain-side selection gate line SGD. The voltage Vsgd is a voltage for causing the drain-side selection transistor STD to be in the ON state (conductive state). In addition, from the time t12, the control circuit 14 applies a voltage Vpass_read to the unselected word line WL. The voltage Vpass_read is a voltage for causing the unselected memory cell transistor MT to be in the ON state (conductive state) regardless of the threshold state of the unselected memory cell transistor MT. The voltage Vsgs, the voltage Vsgd, and the voltage Vpass_read are continuously applied until the time t15, for example.

During a period from a time t13 to a time tl4, the control circuit 14 applies a voltage Vcgr to the selected word line WL. By applying the voltage Vcgr, the selected memory cell transistor MT having a threshold voltage to the extent equal to or higher than the voltage Vcgr maintains an OFF state (non-conductive state). The selected memory cell transistor MT having a threshold voltage to the extent lower than the voltage Vcgr is in the ON state (conductive state). Furthermore, in this state, the sense amplifier module 17 determines whether or not a current flows in the channel layer 62 of the memory pillar MH on the basis of the voltage of the bit line BL. Accordingly, data reading operation is performed.

FIG. 13 is an explanatory cross-sectional view showing reading operation of the semiconductor storage device 1. In reading operation, as described above, the voltage Vsgs is applied to the conductive layer 41A, and the inversion layer 50r is formed in the semiconductor layer 50. For this reason, when the selected memory cell transistor MT is in the ON state (conductive state), electrons move between the channel layer 62 of the memory pillar MH and the second wiring 76 via the inversion layer 50r and the third semiconductor portion 53. Accordingly, a current flows between the bit line BL and the second wiring 76.

### <8.2 Writing Operation>

Next, writing operation will be described.

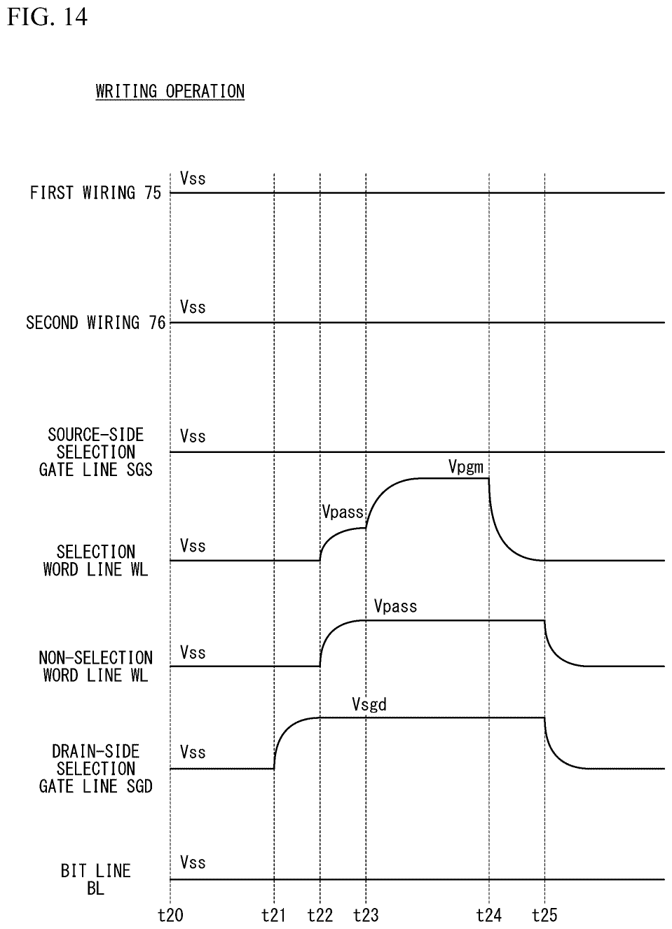

FIG. 14 is an explanatory view showing writing operation. Here, the memory cell transistor MT that is a data writing target will be referred to as “a selected memory cell transistor MT”. The word line WL corresponding to the selected memory cell transistor MT will be referred to as “a selected word line WL”. On the other hand, the memory cell transistor MT that is not a data writing target will be referred to as “an unselected memory cell transistor MT”. The word line WL corresponding to the unselected memory cell transistor MT will be referred to as “an unselected word line WL”. The bit line BL means the bit line BL corresponding to the selected memory cell transistor MT.

As shown in FIG. 14, at a time t20, the first wiring 75, the second wiring 76, the source-side selection gate line SGS, the selected word line WL, the unselected word line WL, the drain-side selection gate line SGD, and the bit line BL have the ground potential Vss (for example, 0 V) under the control of the control circuit 14.

From a time t21, the control circuit 14 applies the voltage Vsgd to the drain-side selection gate line SGD. The voltage Vsgd is a voltage for causing the drain-side selection transistor STD to be in the ON state (conductive state). The voltage Vsgd is continuously applied until a time t25, for example.

From a time t22, the control circuit 14 applies a voltage Vpass to the selected word line WL and the unselected word line WL. Vpass is a sufficiently high voltage for causing the memory cell transistor MT to be in the ON state but is a sufficiently low voltage for preventing the memory cell transistor MT from writing. The voltage Vpass is continuously applied to the unselected word line WL until the time t25, for example.

During a period from a time t23 to a time t24, the control circuit 14 applies a voltage Vpgm to the selected word line WL. The voltage Vpgm is a voltage higher than the voltage Vpass. The voltage Vpgm is a voltage for writing data in the memory cell transistor MT (changing the threshold state of the memory cell transistor MT). By applying the voltage Vpgm, a significant potential difference due to the voltage Vpgm and the voltage Vss is formed between the selected word line WL and the channel layer 62 of the memory cell transistor MT. As a result, electrons are implanted into the selected memory cell transistor MT, and data writing is performed.

### <8.3 Erasing Operation>

Next, erasing operation will be described.

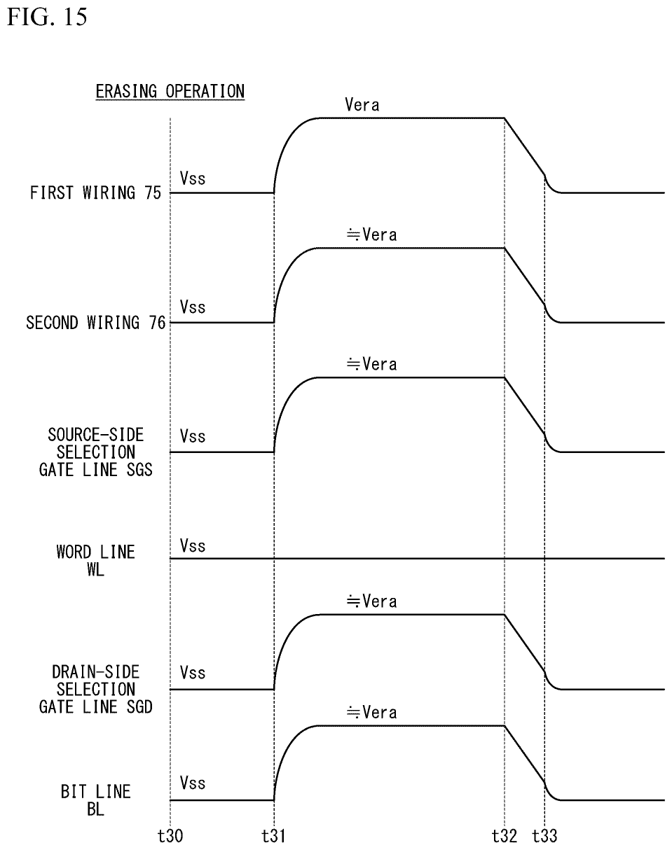

FIG. 15 is an explanatory view showing erasing operation. As shown in FIG. 15, at a time t30, the first wiring 75 and the word line WL have the ground potential Vss (for example, 0 V) under the control of the control circuit 14. In addition, the second wiring 76, the source-side selection gate line SGS, the drain-side selection gate line SGD, and the bit line BL are in a floating state under the control of the control circuit 14.

During a period from a time t31 to a time t32, the control circuit 14 applies a voltage Vera to the first wiring 75. The voltage Vera is a voltage higher than the voltage Vss. As a result, the voltages of the second wiring 76, the source-side selection gate line SGS, the drain-side selection gate line SGD, and the bit line BL rise to a voltage close to the voltage Vera (≈Vera). Accordingly, holes are generated in the second semiconductor portion 52, and the generated holes are supplied to the memory cell transistor MT. Accordingly, electrons are extracted from the memory cell transistor MT, and data is erased.

The control circuit 14 discharges the first wiring 75 from the time t32. As a result, the voltages of the second wiring 76, the source-side selection gate line SGS, the drain-side selection gate line SGD, and the bit line BL which have risen to a voltage close to the voltage Vera (≈Vera) drop toward the voltage Vss.

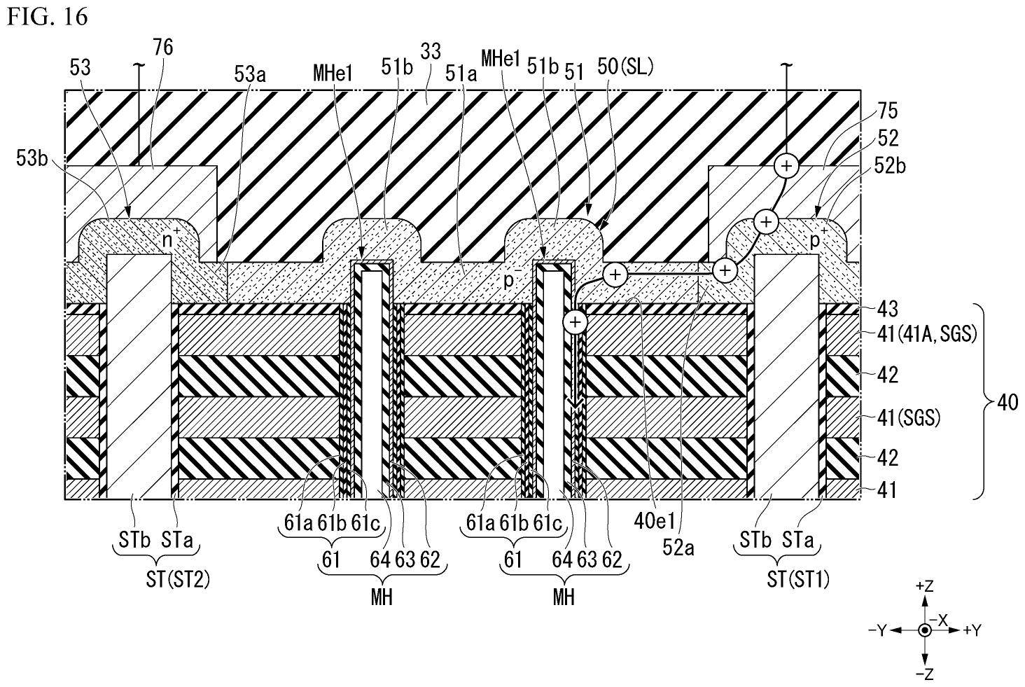

FIG. 16 is an explanatory cross-sectional view showing erasing operation of the semiconductor storage device 1. In erasing operation, as described above, holes are generated in the second semiconductor portion 52, and the generated holes are supplied to the memory cell transistor MT via the first semiconductor portion 51 and the channel layer 62 of the memory pillar MH. Accordingly, electrons are extracted from the memory cell transistor MT, and data is erased.

### 9. Advantages

As a comparative example, a constitution of supplying holes by means of a gate-induced drain leakage (GIDL) current during erasing operation will be considered. In this constitution, there is a need to implant impurities such as phosphorus into a deep part of the channel layer 62 of the memory pillar MH and perform amorphization by performing annealing processing. However, it is not easy to implant impurities into a deep part of the channel layer 62 and perform amorphization by performing annealing processing. For this reason, there is a probability of the insufficient GIDL current during erasing operation. As a result, electrical characteristics of the semiconductor storage device may deteriorate.

On the other hand, the semiconductor storage device 1 of the present embodiment has the semiconductor layer 50, a first wiring 56, and a second wiring 57. The semiconductor layer 50 includes the first semiconductor portion 51, the second semiconductor portion 52, and the third semiconductor portion 53. The first semiconductor portion 51 includes the first part 51a disposed along the first end 40e1 of the multi-layered body 40, and the second part 51b covering the first end portion MHe1 of the memory pillar MH. The second semiconductor portion 52 is connected to the first semiconductor portion 51. The third semiconductor portion 53 is connected to the first semiconductor portion 51. The first wiring 56 is electrically connected to the second semiconductor portion 52. The second wiring 57 is electrically connected to the third semiconductor portion 53. The first semiconductor portion 51 and the second semiconductor portion 52 contain impurities forming a p-type semiconductor. The third semiconductor portion 53 contains impurities forming an n-type semiconductor. When viewed in the Z direction, the conductive layer 41A includes the part 41Aa overlapping the first semiconductor portion 51.

According to such a constitution, during erasing operation, holes can be generated by the second semiconductor portion 52 (p-type semiconductor) and supplied to the memory cell transistor MT. For this reason, insufficiency of erasing operation can be suppressed so that improvement in electrical characteristics of the semiconductor storage device 1 can be achieved.

In the present embodiment, the third semiconductor portion 53 is provided on the first end 40e1 of the multi-layered body 40. According to such a constitution, it is easy for electrons to move between the inversion layer 50r and the third semiconductor portion 53 formed near the first end 40e1 of the multi-layered body 40 among the first semiconductor portion 51. Accordingly, electrical characteristics of the semiconductor storage device 1 can be further enhanced.

In the present embodiment, the second semiconductor portion 52 contains more impurities forming a p-type semiconductor than the first semiconductor portion 51. According to such a constitution, holes are generated by the second semiconductor portion 52 so that they are likely to be supplied to the memory cell transistor MT. For example, if the second semiconductor portion 52 contains more impurities forming a p-type semiconductor than the first semiconductor portion 51, the contact resistance between the second semiconductor portion 52 and the wiring 75 decreases, and therefore it is easy to generate holes. For this reason, further improvement in electrical characteristics of the semiconductor storage device 1 can be achieved. When only the operation is taken into consideration, it is not essential that the impurity concentration of the second semiconductor portion 52 be higher than the impurity concentration of the first semiconductor portion 51.

In the present embodiment, the distance between the conductive layer 41A and the first semiconductor portion 51 in the Z direction is smaller than the thickness T1 of the insulating layer 42A in the Z direction. According to such a constitution, even if a low voltage is applied to the conductive layer 41A, it is easy to form the inversion layer 50r in the semiconductor layer 50. Accordingly, further improvement in electrical characteristics of the semiconductor storage device 1 can be achieved.

In the present embodiment, the shortest distance between the conductive layer 41A and the first semiconductor portion 51 is equal to or smaller than half the thickness T1 of the insulating layer 42A in the Z direction. According to such a constitution, even if a low voltage is applied to the conductive layer 41A, it is easier to form the inversion layer 50r in the semiconductor layer 50. Accordingly, further improvement in electrical characteristics of the semiconductor storage device 1 can be achieved.

In the present embodiment, the insulating layer 43 and the insulating layers 42 have different compositions. According to such a constitution, even when the insulating layer 43 is thin, it is easy to secure a necessary pressure resistance. Accordingly, further improvement in electrical characteristics of the semiconductor storage device 1 can be achieved.

In the present embodiment, when viewed in the Z direction, the second semiconductor portion 52 overlaps at least a part of the division portion ST1. to such a constitution, the second semiconductor portion 52 is formed utilizing a region where the memory pillars MH are not disposed. Accordingly, it is easy to achieve at least one of miniaturization and high-density mounting of the semiconductor storage device 1.

In the present embodiment, when viewed in the Z direction, the third semiconductor portion 53 overlaps at least a part of the division portion ST2.

According to such a constitution, the third semiconductor portion 53 is formed utilizing a region where the memory pillars MH are not disposed. Accordingly, it is easy to achieve at least one of miniaturization and high-density mounting of the semiconductor storage device 1.

### Second Embodiment

Next, a second embodiment will be described. The second embodiment differs from the first embodiment in that the division portion ST does not have the conductive portion STb. The constituents other than those described below are the same as the constituents of the first embodiment.

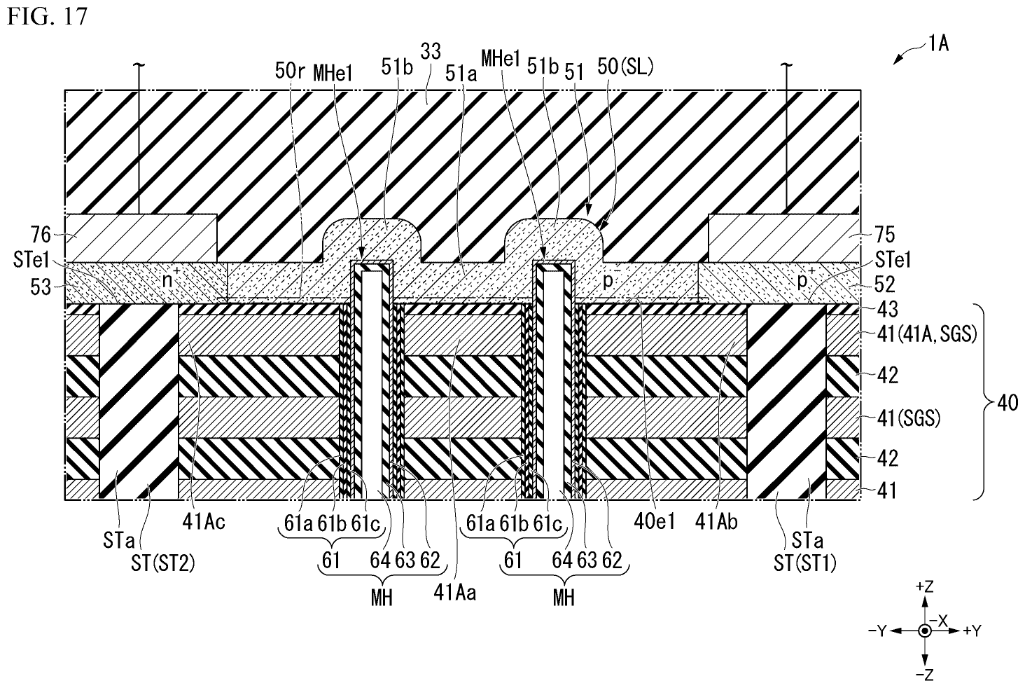

FIG. 17 is a cross-sectional view showing a part of a semiconductor storage device 1A of the second embodiment. In the present embodiment, the division portion ST does not have the conductive portion STb. The entire division portion ST is formed of the insulating portion STa. An end of the division portion ST on the side in the +Z direction matches the first end 40e1 of the multi-layered body 40. For this reason, the second semiconductor portion 52 does not have the second parts 52b. The second semiconductor portion 52 has a layer shape lying in the X direction and the Y direction. Similarly, the third semiconductor portion 53 does not have the second parts 53b. The third semiconductor portion 53 has a layer shape lying in the X direction and the Y direction.

According to such a constitution, a movement path for electrons and holes can be formed by the semiconductor layer 50 so that improvement in electrical characteristics of the semiconductor storage device 1A can be achieved.

### Third Embodiment

Next, a third embodiment will be described. The third embodiment differs from the second embodiment in that the second semiconductor portion 52 is disposed in a region not overlapping the division portion ST in the Z direction. The constituents other than those described below are the same as the constituents of the second embodiment.

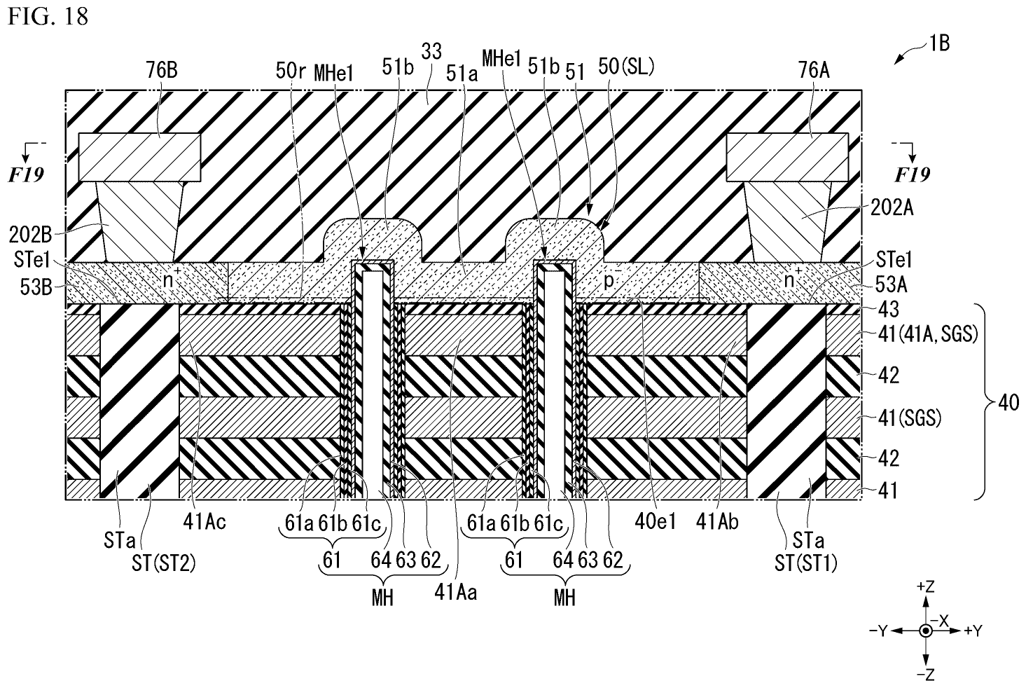

FIG. 18 is a cross-sectional view showing a part of a semiconductor storage device 1B of the second embodiment. In the present embodiment, the semiconductor layer 50 includes the first semiconductor portion 51, the second semiconductor portion 52 (refer to FIG. 19), a semiconductor portion 53A, and a semiconductor portion 53B.

In the present embodiment, each of the semiconductor portion 53A and the semiconductor portion 53B contains impurities (impurities serving as donors) forming an n-type semiconductor and has a conductive type of n-type (for example, n⁺-type). Each of the semiconductor portion 53A and the semiconductor portion 53B is an example of “a third semiconductor portion”. When viewed in the Z direction, the semiconductor portion 53A on one side overlaps at least a part of the division portion ST1. The semiconductor portion 53A linearly extends in the X direction along the division portion ST1 (refer to FIG. 19). When viewed in the Z direction, the semiconductor portion 53B on the other side overlaps at least a part of the division portion ST2. The semiconductor portion 53B linearly extends in the X direction along the division portion ST2 (refer to FIG. 19).

In the present embodiment, the wiring portion 70 includes a wiring 76A and a wiring 76B. The wiring 76A is disposed away from the semiconductor portion 53A in the Z direction. For example, the wiring 76A is disposed at a height not interfering with the bit lines BL. A via 202A is provided between the wiring 76A and the semiconductor portion 53A. The via 202A is a conductive portion extending in the Z direction. In the present embodiment, the via 202A extends in the Z direction and linearly extends in the X direction along the division portion ST1. The wiring 76A is electrically connected to the semiconductor portion 53A via the via 202A. Instead of the foregoing example, the via 202A may not be provided. The wiring 76A may be provided on the semiconductor portion 53A.

Similarly, the wiring 76B is disposed away from the semiconductor portion 53B in the Z direction. For example, the wiring 76B is disposed at a height not interfering with the bit lines BL. A via 202B is provided between the wiring 76B and the semiconductor portion 53B. The via 202B is a conductive portion extending in the Z direction. In the present embodiment, the via 202B extends in the Z direction and linearly extends in the X direction along the division portion ST2. The wiring 76B is electrically connected to the semiconductor portion 53B via the via 202B. Instead of the foregoing example, the via 202B may not be provided. The wiring 76B may be provided on the semiconductor portion 53B.

FIG. 19 is a cross-sectional view taken along line F19-F19 in the constitution shown in FIG. 18. In the present embodiment, the memory cell array 11 includes a first array region AR1 and a second array region AR2 as the array regions AR. The memory cell array 11 has a non-array region NAR between the first array region AR1 and the second array region AR2. The non-array region NAR is a region where the memory pillars MH are not disposed. For example, the non-array region NAR is a region where the memory pillars MH are not present beyond disposition intervals of the memory pillars MH in the array region AR. The memory cell array 11 may have a plurality of non-array regions NAR disposed at certain intervals.

In the present embodiment, the semiconductor layer 50 has the second semiconductor portion 52 in at least a part of the non-array region NAR. The wiring 75 is disposed away from the second semiconductor portion 52 in the Z direction. For example, the wiring 75 is disposed at a height not interfering with the bit lines BL. A via 201 is provided between the wiring 75 and the second semiconductor portion 52. The via 201 is a conductive portion extending in the Z direction. The wiring 75 is electrically connected to the semiconductor portion 53A via the via 201. Instead of the foregoing example, the via 201 may not be provided. The wiring 75 may be provided on the second semiconductor portion 52.

According to such a constitution, a movement path for electrons and holes can be formed by the semiconductor layer 50 so that improvement in electrical characteristics of the semiconductor storage device 1B can be achieved. In the third embodiment described above, the third semiconductor portion (semiconductor portions 53A, 53B) is disposed in the array region AR, and the second semiconductor portion 52 is disposed in the non-array region NAR. In place of this, the second semiconductor portion 52 may be disposed in the array region AR, and the third semiconductor portion 53 may be disposed in the non-array region NAR. In addition, both the second semiconductor portion 52 and the third semiconductor portion 53 may be disposed in the non-array region NAR.

### Fourth Embodiment

Next, a fourth embodiment will be described. The fourth embodiment differs from the third embodiment in that the second semiconductor portion 52 is disposed in the hookup region FR. The constituents other than those described below are the same as the constituents of the third embodiment.

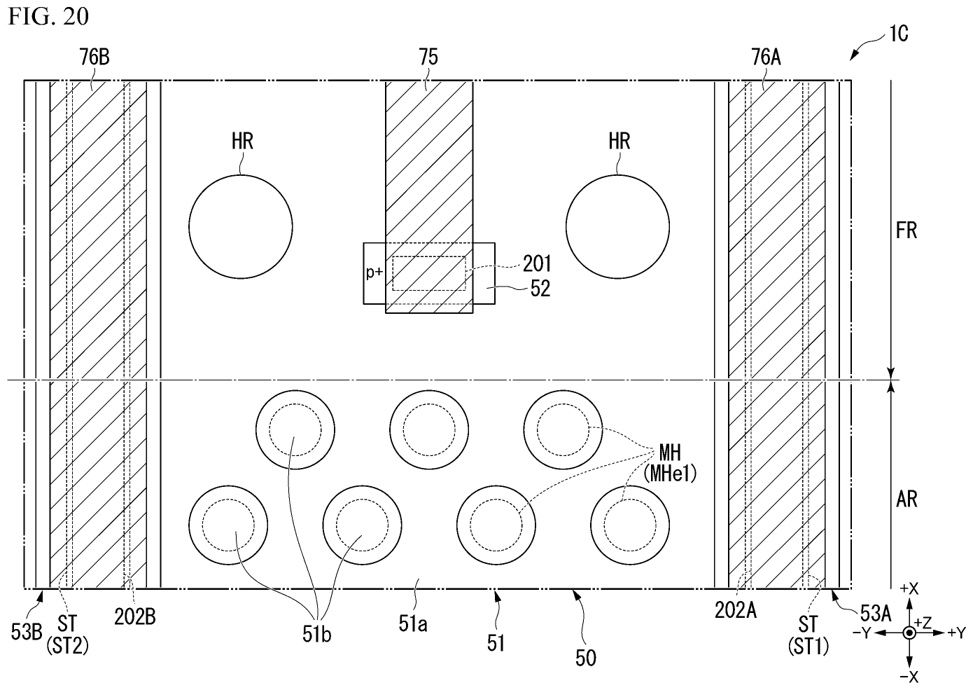

FIG. 20 is a plan view showing a part of a semiconductor storage device 1C of the fourth embodiment. In the present embodiment, the semiconductor layer 50 includes the first semiconductor portion 51, the second semiconductor portion 52, the semiconductor portion 53A, and the semiconductor portion 53B.

At least a part of the semiconductor portion 53A is disposed in the array region AR. At least a part of the semiconductor portion 53B is disposed in the array region AR. On the other hand, the second semiconductor portion 52 is provided in the hookup region FR. The hookup region FR is a region where the memory pillars MH are not disposed. For example, the second semiconductor portion 52 is disposed between two supports HR.

According to such a constitution, a movement path for electrons and holes can be formed by the semiconductor layer 50 so that improvement in electrical characteristics of the semiconductor storage device 1C can be achieved. In addition, in the present embodiment, the second semiconductor portion 52 is formed utilizing a region where the memory pillars MH are not disposed. Accordingly, it is easy to achieve at least one of miniaturization and high-density mounting of the semiconductor storage device 1C. Instead of the foregoing example, the third semiconductor portion 53 may be disposed in the hookup region FR, or both the second semiconductor portion 52 and the third semiconductor portion 53 may be disposed in the hookup region FR.

### Fifth Embodiment

Next, a fifth embodiment will be described. The fifth embodiment differs from the third embodiment in that the second semiconductor portion 52 overlaps dummy memory pillars DMH in the Z direction. The constituents other than those described below are the same as the constituents of the third embodiment.

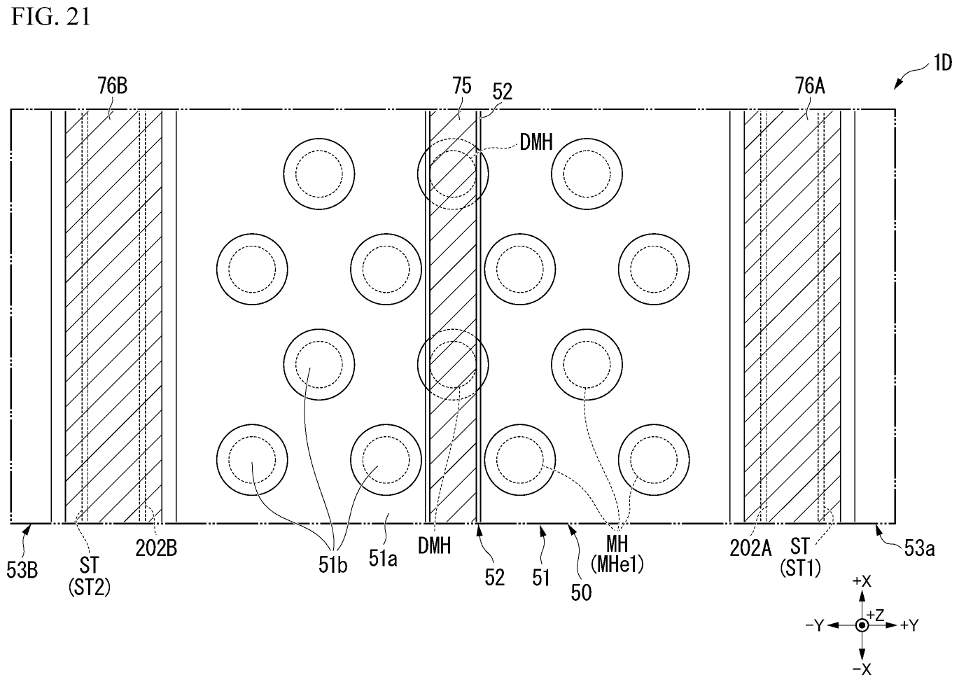

FIG. 21 is a plan view showing a part of a semiconductor storage device 1D of the fifth embodiment. In the present embodiment, in the array region AR, the second semiconductor portion 52 is disposed in a region overlapping the dummy memory pillars DMH. The dummy memory pillars DMH are the memory pillars MH which are not used for retaining valid data. For example, the dummy memory pillars DMH are disposed at positions overlapping the division portions SHE in the Z direction and are not connected to the bit lines BL.

According to such a constitution, a movement path for electrons and holes can be formed by the semiconductor layer 50 so that improvement in electrical characteristics of the semiconductor storage device 1D can be achieved. In addition, in the present embodiment, the second semiconductor portion 52 is formed utilizing a region where the memory pillars MH are not disposed. Accordingly, it is easy to achieve at least one of miniaturization and high-density mounting of the semiconductor storage device 1D. Instead of the foregoing example, the third semiconductor portion 53 may be disposed in a region overlapping the dummy memory pillars DMH, or both the second semiconductor portion 52 and the third semiconductor portion 53 may be disposed in a region overlapping the dummy memory pillars DMH.

Hereinabove, some embodiments have been described, but the embodiments are not limited to the foregoing examples. For example, the plurality of embodiments may be realized by being combined together.

According to at least one of the embodiments described above, a semiconductor storage device includes a first chip and a second chip. The second chip has a multi-layered body, a columnar body, a semiconductor layer, a first wiring, and a second wiring. The multi-layered body includes a plurality of gate electrode layers and a plurality of insulating layers. The plurality of gate electrode layers and the plurality of insulating layers are alternately stacked one by one in a first direction. The multi-layered body has a first end that is an end on a first side in the first direction that is a side opposite to the first chip. The columnar body extends in the first direction inside the multi-layered body. The columnar body has a first end portion reaching at least the first end of the multi-layered body. The semiconductor layer has a first semiconductor portion, a second semiconductor portion, and a third semiconductor portion. The first semiconductor portion includes a first part disposed along the first end of the multi-layered body, and a second part covering the first end portion of the columnar body.

The second semiconductor portion is connected to the first semiconductor portion. The third semiconductor portion is connected to the first semiconductor portion. The first wiring is electrically connected to the second semiconductor portion. The second wiring is electrically connected to the third semiconductor portion. The first semiconductor portion and the second semiconductor portion contain impurities forming a p-type semiconductor. The third semiconductor portion contains impurities forming an n-type semiconductor. A first gate electrode layer closest to the first end of the multi-layered body among the plurality of gate electrode layers includes a part overlapping the first semiconductor portion when viewed in the first direction. According to such a constitution, improvement in electrical characteristics of the semiconductor storage device can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a first chip; and
a second chip adhered to the first chip, wherein
the second chip includes
a multi-layered body including a plurality of gate electrode layers and a plurality of insulating layers, the plurality of gate electrode layers and the plurality of insulating layers being alternately stacked one by one in a first direction, the multi-layered body having a first end, the first end being an end on a first side in the first direction, the first side in the first direction being a side opposite to the first chip,
a columnar body extending in the first direction inside the multi-layered body, the columnar body having a first end portion reaching at least the first end of the multi-layered body,
a semiconductor layer having a first semiconductor portion, a second semiconductor portion, and a third semiconductor portion, the first semiconductor portion including a first part and a second part, the first part being along the first end of the multi-layered body, the second part covering the first end portion of the columnar body, the second semiconductor portion being connected to the first semiconductor portion, the third semiconductor portion being connected to the first semiconductor portion,
a first wiring electrically connected to the second semiconductor portion, and
a second wiring electrically connected to the third semiconductor portion, and wherein
the first semiconductor portion and the second semiconductor portion contain impurities forming a p-type semiconductor,
the third semiconductor portion contains impurities forming an n-type semiconductor,
the plurality of gate electrode layers include a first gate electrode layer closest to the first end of the multi-layered body,
the first gate electrode layer includes a part overlapping the first semiconductor portion when viewed in the first direction.

2. The semiconductor storage device according to claim 1, wherein
the third semiconductor portion is on the first end of the multi-layered body.

3. The semiconductor storage device according to claim 1, wherein
an amount of impurities contained in the second semiconductor portion forming a p-type semiconductor is greater than those of the first semiconductor portion.

4. The semiconductor storage device according to claim 1, wherein
the plurality of gate electrode layers include a second gate electrode layer and a third gate electrode layer,
the third gate electrode layer is adjacent to the second gate electrode layer in the first direction,
the plurality of insulating layers include a first insulating layer between the second gate electrode layer and the third gate electrode layer, and
a distance between the first gate electrode layer and the first semiconductor portion in the first direction is smaller than a thickness of the first insulating layer in the first direction.

5. The semiconductor storage device according to claim 4, wherein
the distance between the first gate electrode layer and the first semiconductor portion in the first direction is equal to or smaller than half the thickness of the first insulating layer in the first direction.

6. The semiconductor storage device according to claim 4, wherein
the multi-layered body includes a second insulating layer between the first gate electrode layer and the first end of the multi-layered body, and
the second insulating layer is different the first insulating layer in composition.

7. The semiconductor storage device according to claim 6, wherein
the first insulating layer is an insulating layer formed by supplying a raw material gas, and
the second insulating layer is a thermal oxide film.

8. The semiconductor storage device according to claim 1 further comprising:
a first division portion extending in the first direction inside the multi-layered body, the first division dividing each of the plurality of gate electrode layers in a second direction intersecting the first direction, wherein
the second semiconductor portion overlaps at least a part of the first division portion when viewed in the first direction.

9. The semiconductor storage device according to claim 1 further comprising:
a second division portion extending in the first direction inside the multi-layered body, the second division portion dividing each of the plurality of gate electrode layers in a second direction intersecting the first direction, wherein
the third semiconductor portion overlaps at least a part of the second division portion when viewed in the first direction.

10. A method of manufacturing a semiconductor storage device comprising:
forming a multi-layered body by alternately stacking a first layer and a second layer above a semiconductor substrate in a first direction;
forming a columnar body extending in the first direction inside the multi-layered body, the columnar body including a first end portion reaching the semiconductor substrate;
eliminating at least a part of the semiconductor substrate;
supplying impurities forming a p-type semiconductor in a part of a semiconductor layer covering the first end portion of the columnar body; and
supplying impurities forming an n-type semiconductor in another part of the semiconductor layer.
